(19) United States
(12) Patent Application Publication
(10) Pub. No.: US 2025/0334628 A1
(43) Pub. Date: Oct. 30, 2025

(54) APPARATUSES AND METHODS FOR TESTING ELECTRONIC DEVICES

(71) Applicant: Delta Design, Inc., Poway, CA (US)

(72) Inventors: Larry R. Stuckey, San Diego, CA (US); Alton R. Lindsey, JR., El Cajon, CA (US); Anton Schuster, Grassau (DE); Jerry Ihor Tustaniwskyj, San Juan Capistrano, CA (US); Stephen Aloysius Wetzel, San Diego, CA (US); Thanh Trieu, San Diego, CA (US); Stefan Binder, Brannenburg (DE); Luis Antonio Müller, San Diego, CA (US); Troy Taylor, Lakeside, CA (US); Tyler Bryan Bettendorf, La Mesa, CA (US)

(73) Assignee: Delta Design, Inc., Poway, CA (US)

(21) Appl. No.: 19/186,350

(22) Filed: Apr. 22, 2025

Related U.S. Application Data
(60) Provisional application No. 63/638,359, filed on Apr. 24, 2024.
(60) Provisional application No. 63/768,669, filed on Mar. 7, 2025.

(51) Int. Cl. G01R 31/28

(52) U.S. Cl. CPC G01R 31/2867; G01R 31/2891; G01R 31/2893

(57) ABSTRACT

A carrier assembly may include a carrier comprising a coupon receptacle configured to engage therein a coupon, the coupon having a device pocket to retain therein a device under test (DUT) during electrical testing thereof and having one or more bottom openings for the DUT to contact a contactor during the electrical testing. A carrier assembly may include a plurality of elastic members configured to be independently elastically elongated to adjust a position of the coupon in the coupon receptacle into a testing position in which the DUT makes electrical and physical contact with the contactor.

### INCORPORATION BY REFERENCE TO ANY PRIORITY APPLICATIONS

Any and all applications for which a foreign or domestic priority claim is identified in the Application Data Sheet as filed with the present application are hereby incorporated by reference under 37 CFR 1.57.

This application claims the priority benefit under 35 U.S.C. § 119(e) to U.S. Provisional Patent Application No. 63/638,359, filed Apr. 24, 2024, entitled “SYSTEM FOR TESTING ELECTRONIC COMPONENTS,” and U.S. Provisional Patent Application No. 63/768,669, filed Mar. 7, 2025, entitled “DEVICE TRAY INPUT AND OUTPUT ASSEMBLY FOR ELECTRONIC DEVICE TESTING SYSTEM.” The content of each of these applications is hereby expressly incorporated by reference in its entirety.

### BACKGROUND

### Technical Field

Embodiments of this disclosure relate to systems for testing electronic devices and methods of testing electronic devices. More particularly, embodiments relate to a system with a plurality of stations for testing the electronic devices, and carrier assembly configured to hold each device during the testing process.

### Description of Related Technology

Automated Test Equipment (ATE) is used in the semiconductor industry to test semiconductor devices. Generally, the automated testing equipment is configured to receive a batch or “lot” of semiconductor devices for testing. The ATE conducts testing based on predetermined settings which are dependent upon the characteristics of each device input into the ATE for testing. During actual testing, various testing systems configured to manipulate the input device's operating conditions are applied to the input device and the result is recorded.

In general, electronic devices to be tested are first placed into a tray which may be loaded into an ATE. Many types of trays are available. For example, JEDEC matrix trays may be used. These trays have standard dimensions of 12.7×5.35 inches (322.6×136 mm). Variations of these trays, such as low profile trays, with a thickness of approximately 0.25-inch (6.35 mm) can accommodate many standard electronic devices, including Ball Grid Array (BGA), Chip Scale Package (CSP), Quad Flat Package (QFP), Quad Flat No-Lead (QFN), Thin Small Outline Package (TSOP) and Small Outline Integrated Circuit (SOIC) type packaging, among many other types. High-profile JEDEC matrix trays with a height of 0.40-inches (10.16 mm) may be used to hold thicker electronic devices such as Plastic Leaded Chip Carrier (PLCC), Ceramic Quad Flat Package (CERQUAD), Pin Grid Arrays (PGA), and other modules and assemblies.

The electronic devices to be tested may be moved within the ATE by robotic equipment from the tray into various stations for running the various tests to confirm the functions of the device. During electrical testing, the electronic device is first connected to a contactor which includes a set of pins. These pins come into contact with the leads or solder balls of the device during electrical testing. Contact elements are commonly composed of a beryllium-copper base metal with gold-plating on the surface. During testing, each electronic device is inserted into the contactor for an electrical connection to the tester.

### SUMMARY

In a first aspect, a coupon includes a device pocket is configured to retain an IC device therein during electrical testing of the IC device. The device pocket has a top opening for receiving the IC device and a bottom surface having formed therethrough a plurality of access openings configured to expose portions of the IC device.

In a second aspect, a carrier assembly for testing integrated circuit (IC) devices includes a plurality of coupon pockets configured to hold a plurality of coupons therein, where each coupon is according to the first aspect.

In a third aspect, an apparatus for testing integrated circuit (IC) devices includes a plurality of stations each having a carrier retainer disk configured to hold and transfer one or more carrier assemblies, where each carrier assembly is according to the carrier assembly of the second aspect.

In a fourth aspect, a carrier assembly for testing an electronic device includes a carrier including a coupon receptacle configured to engage therein a coupon. The coupon includes a device pocket to retain therein a device under test (DUT) during electrical testing thereof and having one or more bottom openings for the DUT to contact a contactor during the electrical testing. The carrier assembly additionally includes a plurality of elastic members configured to be independently elastically elongated to adjust a position of the coupon in the coupon receptacle into a testing position in which the DUT makes electrical and physical contact with the contactor.

In a fifth aspect, an apparatus for testing an electronic device includes a testing station configured to receive a carrier assembly carrying a device under test (DUT) and perform electrical testing on the DUT in the carrier assembly. The carrier assembly includes a carrier including a coupon receptacle configured to engage therein a coupon, the coupon having a device pocket to retain therein the DUT during the electrical testing thereof and having one or more bottom openings for the DUT to contact a contactor during the electrical testing, and a plurality of elastic members configured to be independently elastically elongated to adjust a position of the coupon in the coupon receptacle into a testing position in which the DUT makes electrical and physical contact with the contactor.

In a sixth aspect, a method of testing an electronic device includes providing a carrier assembly carrying a device under test (DUT) in a testing station to perform electrical testing on the DUT. The carrier assembly includes a carrier including a coupon receptacle configured to engage therein a coupon, the coupon having a device pocket to retain therein the DUT during the electrical testing thereof and having one or more bottom openings for the DUT to contact a contactor during the electrical testing and a plurality of elastic members configured to be independently elastically elongated to adjust a position of the coupon in the coupon receptacle into a testing position in which the DUT makes electrical and physical contact with the contactor. The method additionally includes adjusting the coupon into the testing position and performing the electrical testing on the DUT in the carrier assembly.

### BRIEF DESCRIPTION OF THE DRAWINGS

Embodiments of this disclosure will be described, by way of non-limiting example, with reference to the accompanying drawings.

FIGS. 1A and 1B illustrate perspective front and side views of an electronic device testing system according to various embodiments.

FIG. 1C illustrates a top-down view of the electronic device testing system illustrated in FIGS. 1A and 1B according to various embodiments.

FIG. 1D illustrates a platter assembly for rotating carrier retainer disks around stations of the electronic testing system according to embodiments.

FIG. 2 is an example process of testing devices under test using an electronic device testing system according to various embodiments.

FIGS. 3A-3E illustrate a carrier assembly according to various embodiments.

FIGS. 4A-4E illustrates a coupon according to various embodiments.

FIG. 5A illustrates portions of a testing station according to various embodiments.

FIG. 5B illustrates a cross section of a testing site according to various embodiments.

FIGS. 6A and 6B illustrate an example socket layout kit according to various embodiments.

FIG. 6C illustrates a nest plunger according to various embodiments.

FIG. 7 illustrates a socket according to various embodiments.

FIG. 8 illustrates a loadboard according to various embodiments.

FIGS. 9A and 9B illustrate a tray precising system 106 according to various embodiments.

FIGS. 10A-10C illustrate a tray frame according to various embodiments.

FIGS. 11A-11C illustrate an automatic tray transferor according to various embodiments.

### DETAILED DESCRIPTION OF CERTAIN EMBODIMENTS

The following detailed description of certain embodiments presents various descriptions of specific embodiments. However, the innovations described herein can be embodied in a multitude of different ways, for example, as defined and covered by the embodiments. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the illustrated elements. Further, some embodiments can incorporate any suitable combination of features from two or more drawings.

### Testing System Overview

Aspects of this disclosure relate to Automated Testing Equipment, also called an “electronic device testing system”, with improved reliability, efficiency and/or cost associated with testing electronic components. The electronic device testing system may provide automation for testing electronic devices or components. The electronic devices can include, but are not limited to, semiconductor device components, including packaged and unpackaged integrated circuit (IC) dies including monolithically integrated IC dies as well as bonded or stacked IC dies that include passive and/or active circuitry. Such dies can include integrated circuits, such as logic circuitry, volatile and nonvolatile memory circuitry, power delivery circuitry, photonic integrated circuitry, to name a few. The electronic devices that are being tested in the electronic testing system may be referred to as devices under test (“DUTs”).

Types of electronic device packages which may be tested within the electronic device testing systems described herein include Ball Grid Arrays (BGA), Chip Scale Packages (CSP), Quad Flat Packages (QFP), Quad Flat No-Leads (QFN), Thin Small Outline Packages (TSOP), Small Outline Integrated Circuit (SOIC), Plastic Leaded Chip Carrier (PLCC), Ceramic Quad Flat Package (CERQUAD), and Pin Grid Arrays (PGA). Other types of packages are also contemplated within embodiments of the invention.

Many challenges of designing electronic device testing systems arise from handling the IC packages, e.g., using vacuum handlers, as they are transferred and probed. One of the challenges is reducing the displacement of a DUT during operation of the testing equipment (sometimes referred to as “device out of pocket”), which is often caused in part due to handling of the DUTs. Another challenge is reducing DUTs being stuck within components of the testing equipment, such as handlers or contactors. Another challenge is keeping the DUTs at a temperature closer to the test temperature prior to testing the individual DUTs to improve throughput. Another challenge is keeping the testing environment substantially dry to reduce condensation on the DUTs that might occur when transported into the testing system from ambient temperature.

To address these and other needs, the disclosed electronic device testing systems are configured to transfer DUTs from a tray into a carrier assembly. The carrier assembly moves through a plurality of stations and through completion of the testing of the DUTs, without transferring the DUTs out of the carrier assembly. The DUTs are carried in the carrier assembly as the carrier assembly is moved from one station to another within the system. The DUTs are retained in the carrier assembly using a plurality of “coupons” that are attached to the carrier assembly, but the coupons are allowed limited lateral and vertical movements and degrees of freedom while being carried in the carrier and placed in the testing station, until the DUTs are tested. Prior to testing in a testing station and/or during pretesting procedures, the coupons may be allowed limited lateral and vertical movements and degrees of freedom. For example, the coupons may at times have up to six degrees of freedom, including three independent linear degrees of freedom and three independent angular degrees of freedom, until the coupons are secured during testing. The six degrees of freedom can help the DUTs within the coupons to properly align with components of the system, such as a contactor. The stations include an electronic testing station where the DUTs are tested in the carrier assembly without being removed from the carrier assembly or the coupons. In the electronic testing station, a contactor electrically contacts the DUTs retained in the carrier assembly to send and receive electrical signals. The signals can include, e.g., testing signals as well as power signals to power the DUTs. The temperature of the DUTs may also be controlled, e.g., actively controlled, during testing using plunger assemblies contacting the DUTs on the opposite side of the contactor. The plunger assemblies may be equipped with an automatic temperature control (ATC) system including a heater and cooler for maintaining a substantially constant temperature DUT temperature during testing. In addition, the contactor may be connected to a cooling system and incorporate a heater to help maintain the DUT at a predetermined temperature during testing.

The system may also include other stations through which the DUTs are transported in carrier assemblies including, for example, a thermal staging area (which can include one or more soak stations) preceding the testing station. To improve throughput, the DUTs may be brought and kept at a temperature closer to the testing temperature prior to testing. To reduce the lag time associated with bringing the DUTs closer to the testing temperature, the one or more soak stations in the thermal staging area and the testing station are enclosed in a thermal chamber under a common temperature-controlled atmosphere.

In some embodiments, the carrier assemblies remain on carrier retainer disks throughout the thermal chamber or the thermal chamber and the dry chamber without being stacked. However, embodiments are not so limited and in some other embodiments, the carrier assemblies may be stacked into a stack and singulated from the stack in the thermal staging area prior to being tested. For example, a carrier assembly may be loaded to a first soak station having a stack of carrier assemblies, raised to the top of the stack as other carrier assemblies are loaded, moved laterally into a second soak station, where it is lowered into position before continuing to the testing station.

In some embodiments, the thermal staging area includes more than one soak station for carrier assemblies. This can create a lag time allowing the carrier assemblies and DUTs to reach their target temperature before moving into the testing station. In some instances, the lag time may be approximately defined by the time used for testing and the number of positions for the carrier assemblies in the thermal staging area.

The thermal chamber keeps the DUTs closer to the testing temperature by circulating temperature-controlled gas such as clean dry air. The thermal chamber may also be held under a positive pressure of clean dry air to minimize any condensation that may occur on the DUTs. In addition, an input station at which the untested DUTs are introduced into carrier assemblies, an output station from which the tested DUTs are unloaded, and a tray precising station (TPS), from which DUTs on a tray in a tray frame are pick-and-placed in the carrier assembly in the input or output station, may also be kept at a positive pressure of clean dry air, which may be at room temperature, in a separate dry chamber to reduce any moisture that may enter into the thermal chamber.

In addition, the disclosed electronic testing systems are configured to transfer the carrier assemblies carrying the DUTs from one station to the next by rotating carrier retainer disks retaining the carriers in a circular pattern using a platter assembly. The carrier assemblies rotate about a vertical axis of the device testing system, without using robotic arms or handlers to move the carrier assemblies. Each carrier retainer disk may also rotate about its own central axis to compensate for the rotation about the vertical axis, such that the carrier assemblies remain substantially aligned in the same direction through completion of the testing. This process maintains each DUT within a carrier in the same position while in the test system and helps reduce jostling and damage that may come from moving the DUTs within the test system during the transfer from station to station. This may also significantly reduce jams caused by displacements of the DUTs or DUTs being stuck on or within testing components or stations.

In addition, the disclosed electronic testing systems include a DUT tray input/output system for transferring untested DUTs onto the carrier assemblies in the thermal chamber and transferring tested DUTs out of the carrier assemblies and out of the thermal chamber back to a tray, using a pick-and-place handler. In one embodiment, the system may use tray frames configured to mate with the trays to pick up and move the trays into and out of the system. The DUT tray input/output system may include as few as three motor drives configured to transfer the trays, held by the tray frames, into and out of the thermal chamber. The DUTs within the trays may be monitored and identified using a vision monitoring system prior to being placed in the carrier assemblies for tracking. The tray frames may be made of an inflexible material, such as metal, so that when they mate with a tray, they can reduce any tray warpage and straighten and align the trays for pick and place precision movement. This may also help to further reduce displacement of DUTs from the trays due to tray warpage.

In some aspects, the electronic device testing system disclosed herein may intake DUTs that are to be tested, index the DUTs, test the DUTs, record the results of testing, and output the indexed and tested DUTs while reducing instances of DUT displacements. The disclosed electronic device testing system may increase DUT throughput, reduce testing stoppage, reduce repairs or other maintenance, and/or provide other benefits.

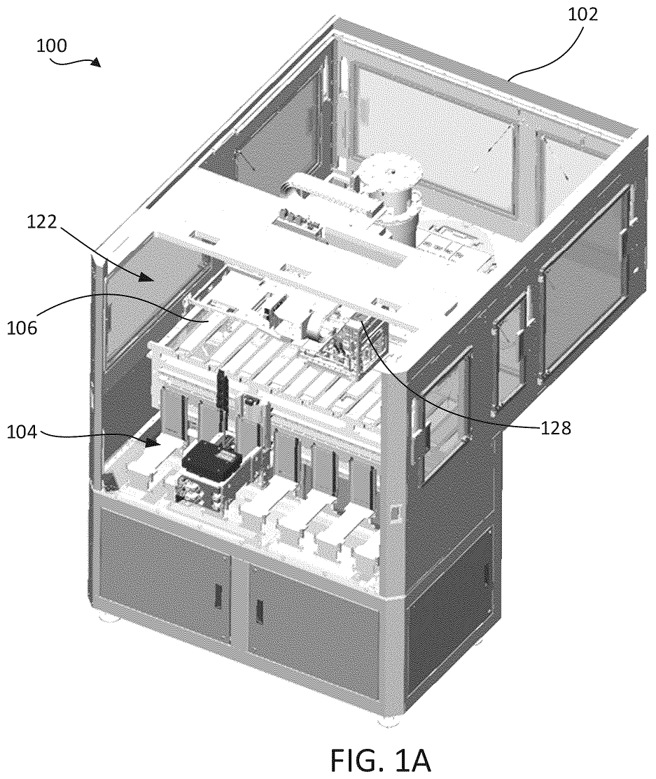

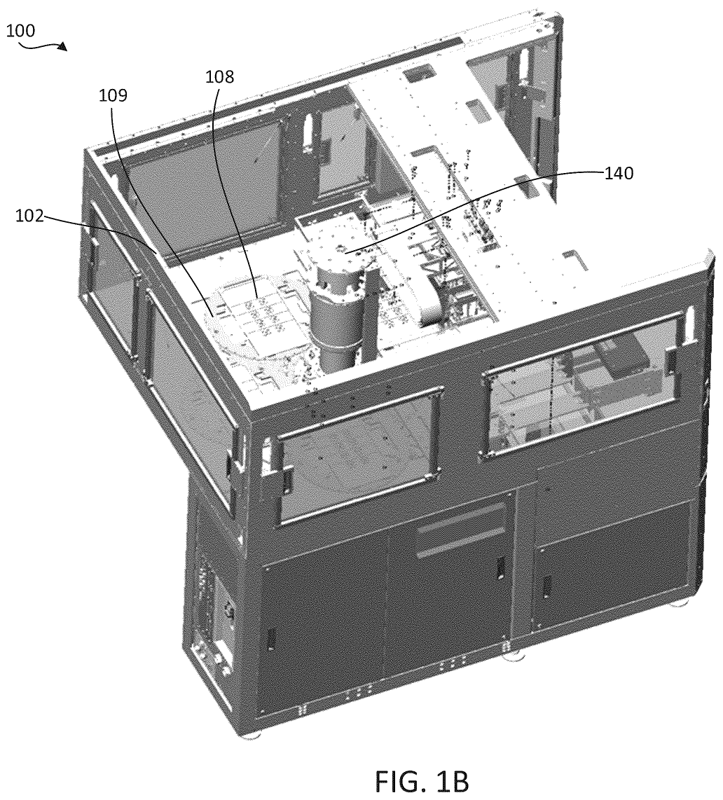

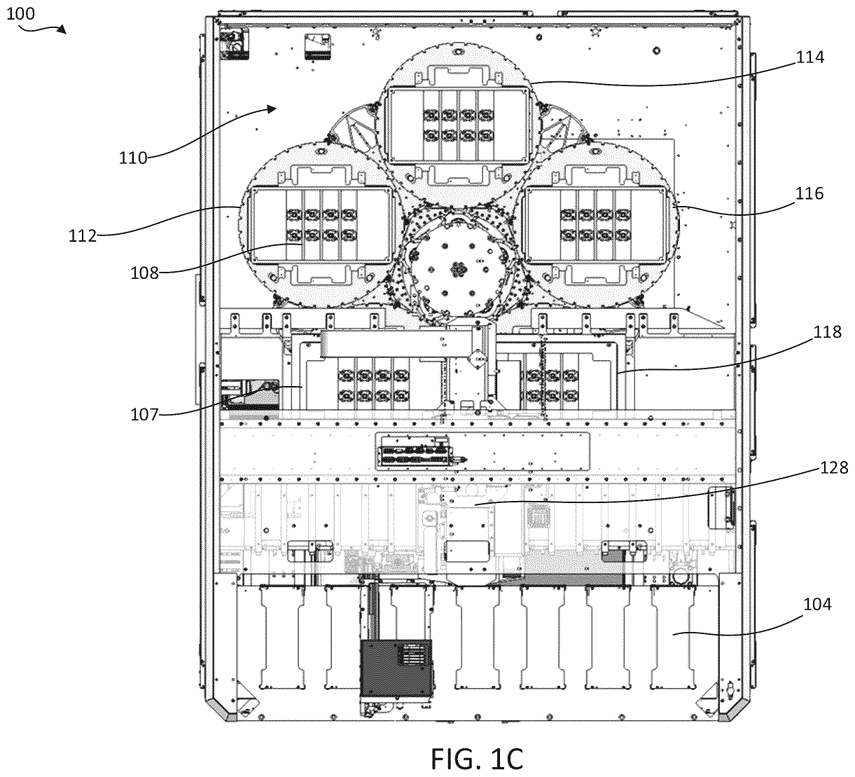

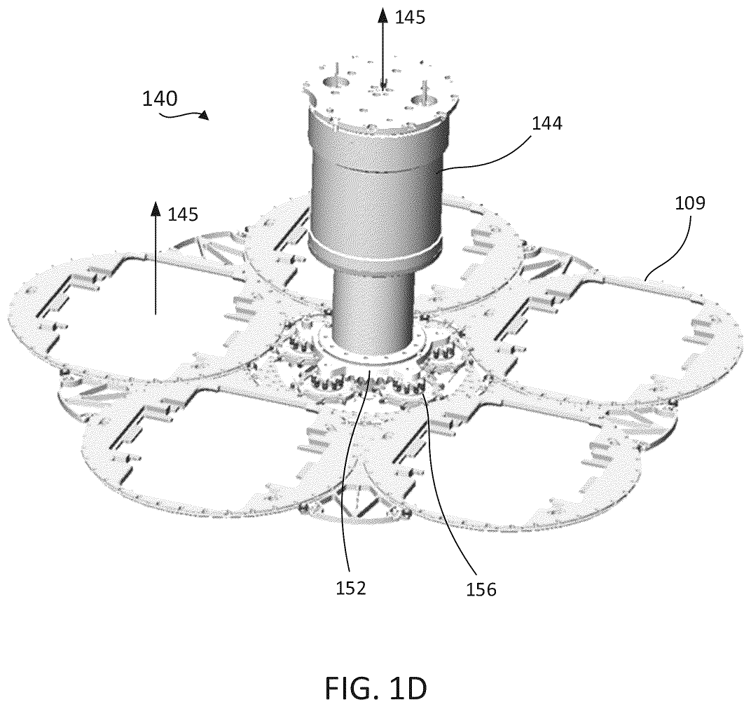

FIGS. 1A-1C illustrate an electronic device testing system 100, according to various embodiments. FIGS. 1A and 1B are perspective front and side views and FIG. 1C is a top-down view of the device testing system 100. In the illustrated embodiment, the electronic device testing system 100 includes tray stacks 104 (FIG. 1A; actual stacks not shown) an input station 107, carriers 108 (FIGS. 1A-1C), carrier retainer disks 109 (FIG. 1B), a thermal staging area 110 (FIG. 1C), which can include one or more soak stations 112, 114 (FIG. 1C), a testing station 116 (FIG. 1C), and an output or sort station 118 (FIG. 1C). In the illustrated embodiment, the electronic device testing system 100 additionally includes a tray precising station (TPS) 106 (FIGS. 1A, 1C) from which DUTs in a tray are transferred into the input station 107 and out of the output station 118 using a pick-and-place (PnP) head 128 (FIGS. 1A, 1C). In the electronic testing system 100, as described above, the one or more soak stations 112, 114 of the thermal staging area 110 and the testing station 116 may be in a thermal chamber 102 (FIGS. 1A, 1B) under temperature-controlled atmosphere under positive pressure to bring DUTs close to testing temperature. The temperature inside the thermal chamber 102 is controlled in part by introducing temperature-controlled gas, e.g., temperature controlled clean dry air. The atmosphere in the thermal chamber 102 may further be controlled, e.g., to reduce the moisture content and condensation on the DUTs. Further, the input station 107, the output station 118 and the TPS 106 may be in a dry chamber 122 (FIG. 1A) under positive pressure to reduce condensation on the DUTs upon introduction into the thermal chamber 102.

In some embodiments, the electronic device testing system 100 may be connected to one or more heat exchangers through inlet and outlet pipes. The heat exchanger may comprise one or more condensers for circulating temperature-controlled gas, e.g., chilled clean dry air, or other gas such as argon, helium, etc. in the thermal chamber 102 and/or the thermal staging area 110 to maintain the temperature-controlled atmosphere therein. In some embodiments, the temperature-controlled gas may be introduced into the thermal chamber 102 and/or the thermal staging area 110 through a temperature-controlled gas conduit disposed close to the thermal staging area 110. Additional heat exchangers may be employed to provide a cold source for one or both of a contactor and a plunger, which may be configured, in conjunction with a heater, to provide automatic temperature control of the DUT during testing. The temperature of the DUT may be maintained, e.g. at a temperature between about −50° C. and 200° C.

Among other technical features described throughout the application, in various embodiments, in operation of the system 100 according to embodiments, the DUTs are transferred within the system 100 through usage of the carriers 108, without handling DUTs out of the carriers 108 as the DUTs are transferred though different stations. Unlike existing systems, once the DUTs are transferred onto the carriers 108, the station-to-station transfers and testing of the DUTs are performed without removing them from the carriers 108, which greatly reduces device displacement events, as there may not be a need for handling the DUTs using, e.g., vacuum handlers, until after the testing is completed. The reduced handling of the DUTs greatly reduces the probability of displacing the DUTs, which has traditionally been one of the biggest throughput limiters of IC testing.

The tray stacks 104 can include trays of DUTs that are to be tested or have completed testing. Each tray in the tray stack 104 can include one or more DUTs. For example, each tray in the tray stack 104 can include one, two, four, eight, twenty, fifty, or other number of DUTs. In the illustrated implementation, the tray stacks 104 are positioned outside of the thermal chamber 102.

In some implementations, in addition to the control of the ambient temperature in the thermal chamber 102, there can also be a pressure difference between the thermal chamber 102 and the area in which the tray stacks 104 are positioned. For example, the thermal chamber 102 may have, e.g., a positive pressure of temperature-controlled dry gas such as air, nitrogen or other inert gas (e.g., He or Ar). The positive pressure may be maintained by a continuous purge of the thermal chamber 102 with the temperature-controlled dry gas. Similarly, the dry chamber 122 may also have a positive pressure, e.g., a positive pressure of temperature-controlled dry gas. The positive pressure configurations can keep moisture from condensing on the DUTs or other parts of the system, which can interfere with the testing. For example, without such purge, DUTs that are cooled may collect excessive moisture condensation.

The TPS 106 can carry, or otherwise transfer, trays from the tray stacks 104 into the thermal chamber 102. In some embodiments, the TPS 106 includes tray frames that temporarily physically couple to a tray of the tray stack 104 and carry the tray into the thermal chamber 102. The TPS 106 can carry, or otherwise transfer trays, such as trays of DUTs having completed testing, from the dry chamber 122 to the tray stacks 104. The TPS 106 can include, or be connected to, the input station 107 and the output station 118.

The PnP head 128 can transfer DUTs from a tray inputted into the dry chamber 122 from the TPS 106 and place them onto carriers 108 on the input station 107. The PnP head 128 can also carry DUTs from a carrier 108 on the output station 118 and place them onto trays in the TPS 106 to be carried out of the dry chamber 122. In various implementations, the input station 107 and the output station 118 can be configured to pick up DUTs one at a time, or in sets. For example, the PnP head 128 can include one or more vacuum contact points to temporarily couple the DUTs to transfer them to the carrier 108 on the input station 107 or from the carrier 108 on the output station 118.

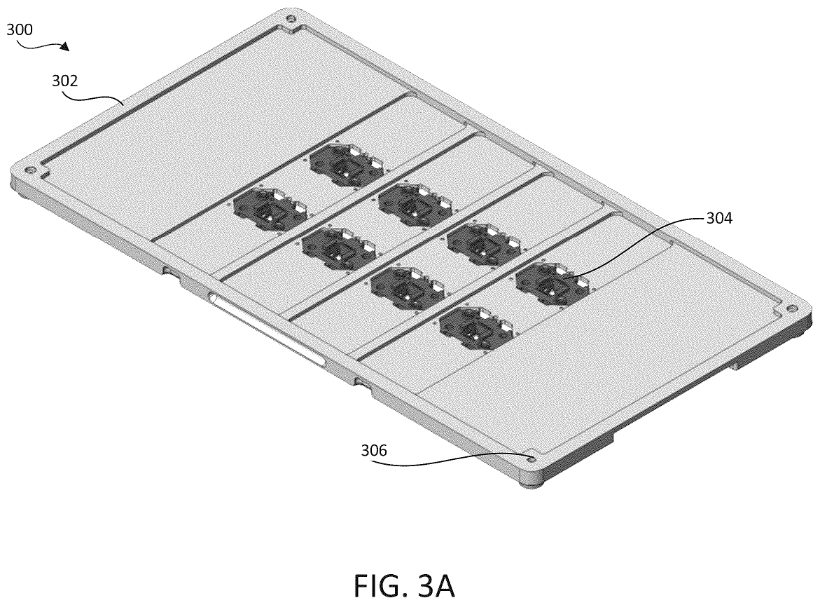

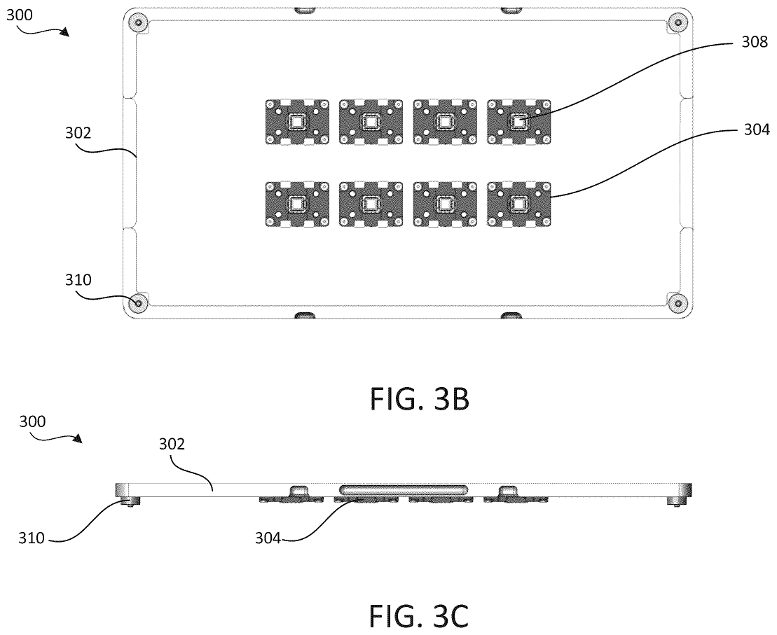

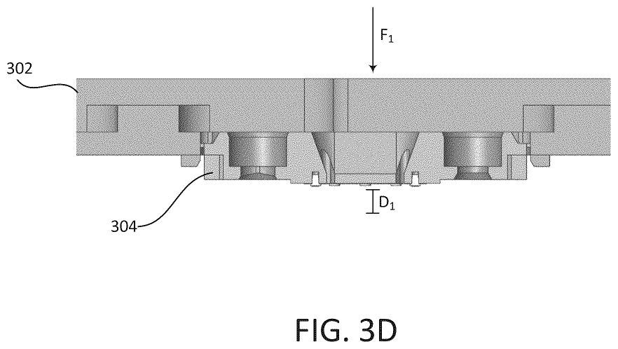

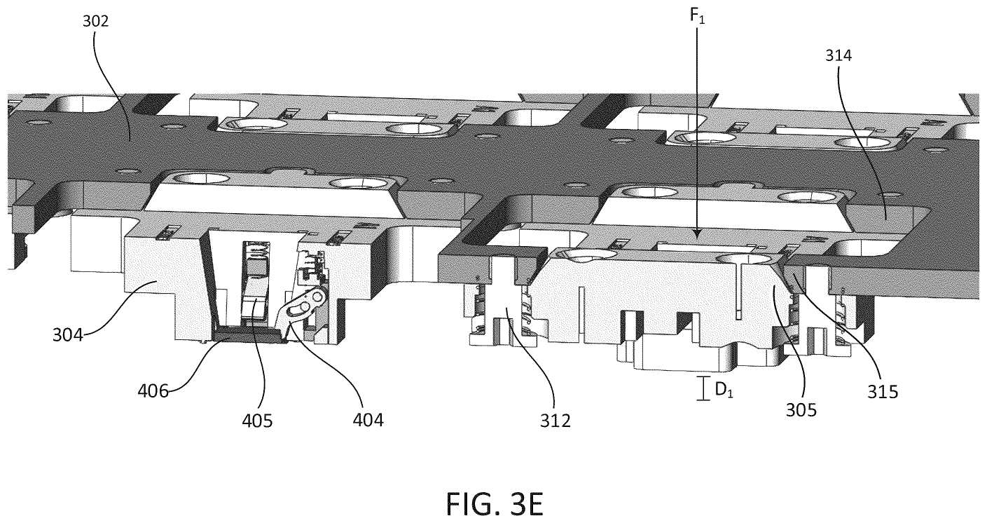

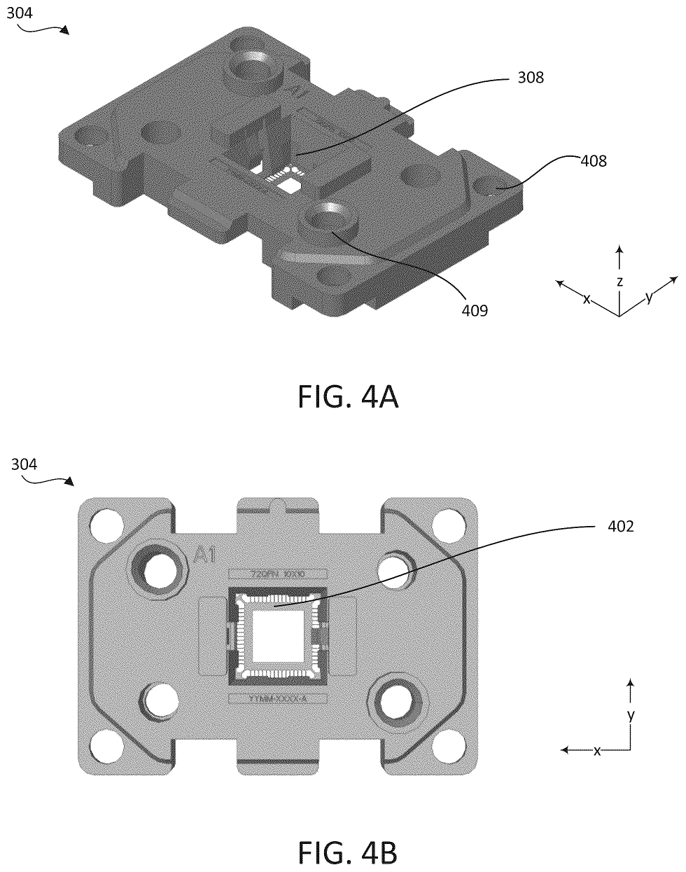

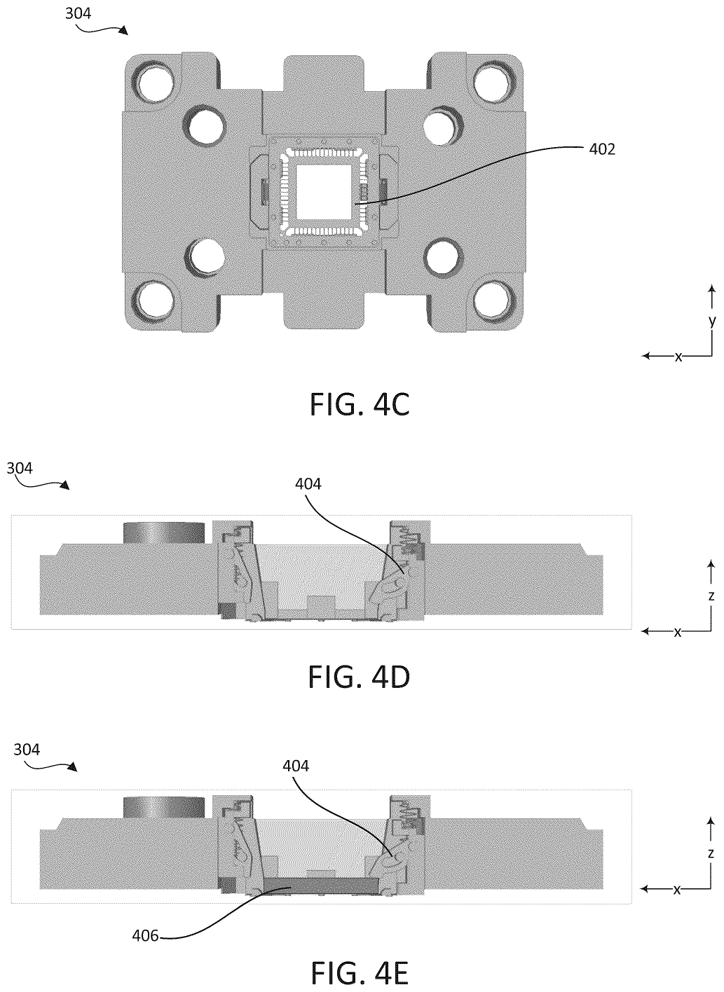

The carriers can include one or more coupons. Each coupon may be configured to carry one or more DUTs. While placed in a carrier, a coupon may have up to six degrees of freedom of movement, including three linear degrees of freedom along lateral, e.g., x and y directions, and the vertical direction, e.g., z direction, and three rotational degrees of freedom about the x, y and z axes. The degrees of freedom may be provided by, e.g., springs holding the coupons within the carrier. The degrees of freedom may allow the coupons to move within the carrier without damaging the coupons and/or dislodging the coupons. The DUT may be secured using one or more securing mechanisms (e.g., the holder 404 and the holder 405, described below with respect to FIG. 3D and FIGS. 4D and 4E). The coupon may allow a testing orientation to remain. For example, the pin orientation of the DUT may be maintained within the coupon as the carriers are transported to the different stations.

The carriers 108 may be transported between different stations by the carrier retainer disks 109. The carrier retainer disks 109 are configured to hold and transfer the carriers 108 from one station to the next. While being transferred, the carriers 108 are coupled or temporarily coupled to the carrier retainer disks 109. In some implementations, the carriers 108 are placed on the carrier retainer disks 109. In the illustrated implementation, the carrier retainer disks 109 rotate the carriers 108 sequentially from the input station 107 to the thermal staging area 110 (which is illustrated as having two soak stations 112, 114), followed by the testing station 116, and followed by the output station 118.

In some embodiments, the carrier retainer disks 109 are configured such that, as they are rotating, the orientations of the carriers 108 are kept substantially constant. For clarity, FIG. 1D shows an example platter assembly 140 configured for such operations. The platter assembly 140 includes a torque motor 144 configured to rotate a platter having a plurality of arms, each having disposed thereon a carrier retainer disk 109 configured to carry a carrier 108. The platter assembly 140 additionally includes a sun gear 152 and a plurality of planet gears 156 each corresponding to a carrier retainer disk 109. The torque motor 144 causes the sun gear 152 to rotate, which in turn causes the planet gears 152 to rotate. The planet gears 152 and the carrier retainer disks 109 are toothed to mesh with each other such that the carrier retainer disks 109 rotate in the opposite sense as the sun gear 152. For example, as the carrier retainer disks 109 are rotating from one station to the next in a clockwise direction about a central axis 125 of the system, they are rotated in a counterclockwise direction to offset for the rotations of the carrier retainer disks 109 about their own local central axes 145.

The thermal staging area 110 can heat the DUTs and/or cool the DUTs to set temperatures, such as a testing temperature (also referred to as “soaking” the DUTs). A testing temperature can refer to a temperature the DUTs are to be at when testing begins. The thermal staging area 110 can include a first soak station 112 and a second soak station 114. In some instances, the time required for a DUT to reach a testing temperature in the thermal staging area 110 may be different (e.g., shorter or longer) than the time required for testing in the testing station 116. The thermal staging area 110 can include multiple soak stations for the carriers 108. The carriers 108 can be brought into a first soak station 112 in the thermal staging area 110 where the carriers 108 are soaked for an amount of time (e.g., approximately the time it takes to complete a test of DUTs in the testing station). Then the carriers 108 can be brought into a second soak station 114 of the thermal staging area 110 where the carriers are further soaked for an amount of time (which can be approximately equal to the amount of time in the first station of the thermal staging area 110).

In embodiments where soak stations are configured to stack and unstack multiple carrier, the carriers 108 can be brought into the first soak station 112 (which may also be referred to as a soak up station) and/or the second soak station 114 (which may also be referred to as a soak down station) by the carrier retainer disks 109 where each new carrier 108 is added to a stack. A carrier 108 can be removed from a stack in the soak up station 112 and/or the soak down station 114 and placed back onto the carrier retainer disks 109. A carrier 108 can remain in a stack in the soak up station 112 and/or soak down station 114. In some implementations, carriers 108 can be rotated by the carrier retainer disks 109 into the soak up station 112 where they can be stacked. Each carrier 108 arriving at the soak up station is inserted into a slot created at the bottom of the stack of carriers 108 such that vertical handling of the carriers is reduced. The DUTs in their respective carriers 108 soak to a temperature setpoint as the carriers 108 are stacked up. The stack of carriers 108 can be rotated by a carrier retainer disk 109 from the soak up station 112 into the soak down station 114, from which the carriers 108 are singulated and moved to the testing station 116.

While FIGS. 1A-1C illustrate the thermal staging area 110 as having two separate soak stations, in various implementations, the thermal staging area 110 may have a single station or more than two stations. In some implementations, the thermal staging area 110 may be omitted altogether and the carriers transferred directly from the input station 107 to the testing station 116. In yet other implementations, the testing station may be between two soak stations 109.

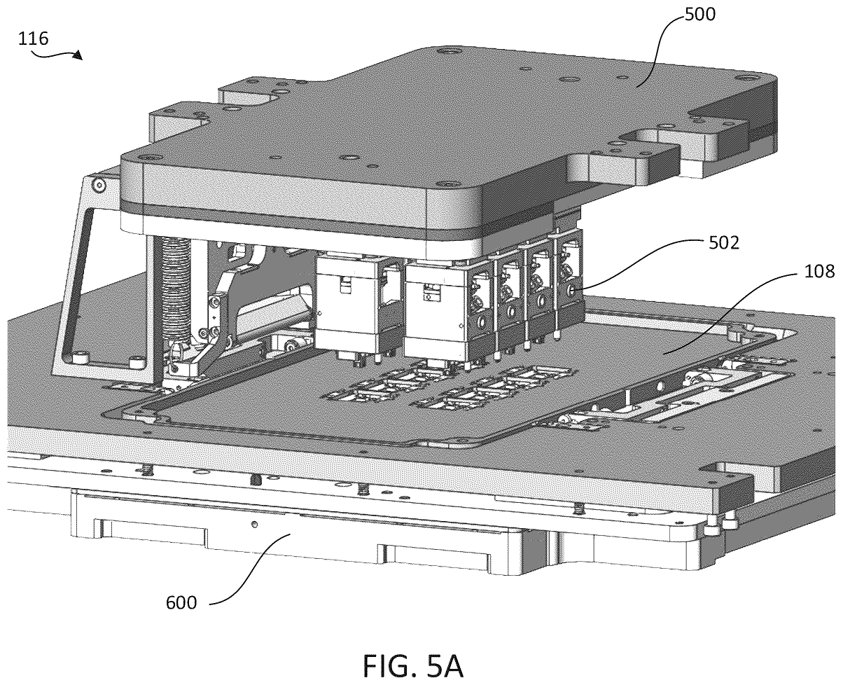

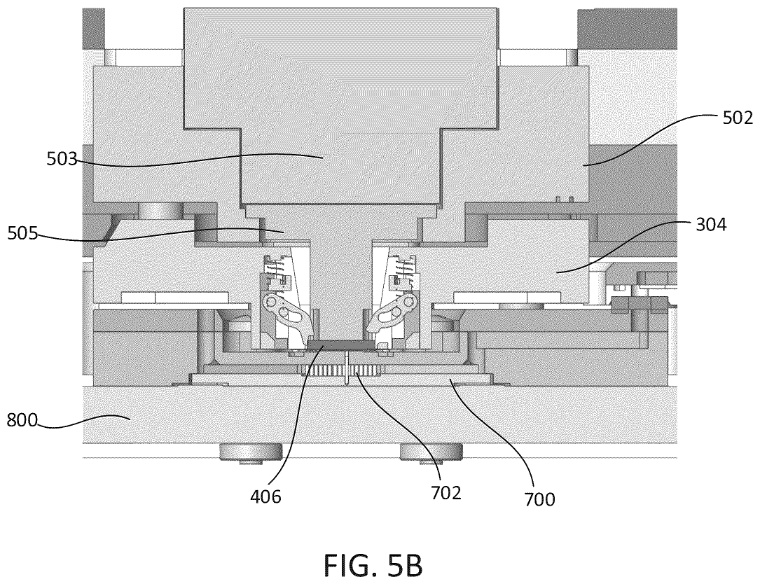

Following the thermal staging area 110, the carriers 108 can rotated into the testing station 116 (also referred to as a “testing chamber”) by the carrier retainer disks 109, where the DUTs undergo electrical testing. The testing station 116 can include contactors that can create an electrical connection while physical contact is made between the contactors and input/output (“I/O”) points of the DUTs (e.g., I/O contact pins, I/O contact pads, and/or the like on the DUTs). The testing station 116 may apply a testing signal to the DUTs. For example, the testing station 116 can apply electrical power or current to the DUTs via the contactors. The testing station 116 can measure one or more parameters of the DUTs during testing. For example, the testing station 116 can measure changes in temperature of the DUTs, output power of the DUTs, and/or other parameters in response to the applied testing signal. The testing station 116 may lock the position of the coupons and/or the position of the DUTs in the coupons, removing any freedom of movement the coupons and/or DUTs within the coupon have during testing. In some implementations, the testing station 116 can include an active thermal control (“ATC”) system that can raise and/or lower temperature of the DUTs during testing. A portion of an example testing station 116 is illustrated in FIG. 5A below.

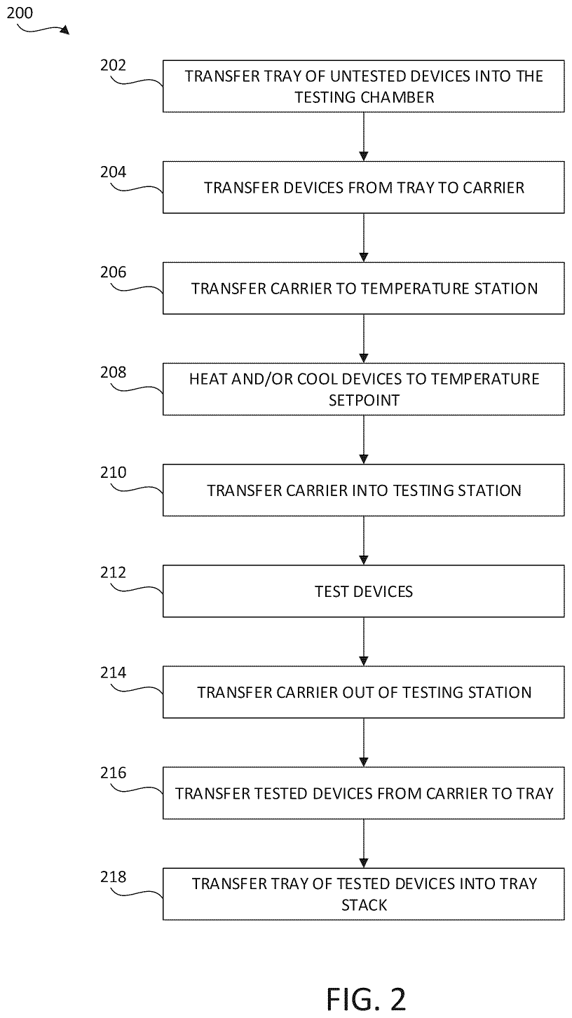

FIG. 2 is an example process 200 of testing DUTs using an electronic device testing system 100, according to various embodiments. Process 200 may contain more, or fewer, steps than illustrated in FIG. 2. Some of the steps of process 200 may be repeated. Further, the steps of process 200 may be performed in other orders than those illustrated in FIG. 2.

At block 202, the electronic device testing system 100 transfers a tray of untested devices or DUTs into the thermal chamber 102. For example, the TPS 106 may use a tray frame to carry a tray of untested devices from the tray stacks 104 into the thermal chamber 102. At block 204, the electronic device testing system 100 transfers devices from the tray into one or more carriers 108. For example, the input station 107 may carry individual ones of the devices from the tray and place them into coupons on the carriers 108. In some implementations, the tray may have a larger number of devices than can be held in a carrier 108. In these implementations, the devices in the tray may be loaded into multiple carriers 108. In other implementations, the tray may have a smaller number of devices than can be held in a carrier 108. In these other implementations, the electronic device testing system 100 may load multiple trays of untested devices into a single carrier 108.

At block 206, the electronic device testing system 100 transfers a carrier 108 into the thermal staging area 110. For example, a carrier retainer disk 109 can rotate the carrier 108 into the thermal staging area 110. In some embodiments, the carrier 108 may be placed in one or more stacks of carriers 108 within the thermal staging area 110.

At block 208, the devices in the carrier 108 are heated and/or cooled to a temperature setpoint within the thermal staging area 110. For example, the thermal staging area 110 may use convection, radiation, and/or other heating processes to heat the devices. As another example, the thermal staging area 110 may use cold gases, heat sinks, and/or other cooling processes to cool the devices. The thermal stating area 110 may also control pressure and/or moisture of its atmosphere. It will be appreciated that, in some embodiments, no heating or cooling may occur, e.g., where the devices are tested at room temperature. At block 210, the carrier 108 is transferred into the testing station 116. For example, the carrier retainer disk 109 can rotate the carrier 108 into the testing station 116.

In some implementations, the carrier 108 may be in the thermal staging area 110 for multiple testing cycles. The thermal staging area 110 can include multiple stations for setting and soaking the temperature of the devices. For example, the thermal staging area 110 can include two stations, three stations, or more stations for setting and soaking the temperature of the DUTs. In some of these implementations, the electronic device testing system 100 may stack carriers 108 in the thermal staging area 110. For example, as the carrier 108 is transferred to the thermal staging area 110 at block 206, the carrier 108 can be removed from the carrier retainer disk 109 and added to the stack. The electronic device testing system 100 may remove the carriers 108 from a stack one by one as they are rotated out of the thermal staging area 110. For example, as a carrier 108 is transferred to the testing station 116 at block 210, the carrier 108 can be removed from a stack and placed on a carrier retainer disk 109 and rotated by the carrier retainer disk 109 into the testing station 116. In some implementations, the devices may not be subjected to heat or cold treatments. In these implementations, the electronic device testing system 100 may cause a carrier 108 to bypass the thermal staging area 110. For example, the carrier 108 may not be added to a stack and continued to be carried through the thermal staging area 110. As another example, the thermal staging area 110 may be omitted in some implementations. In some implementations, carriers 108 are singulated from the stack and transferred to the testing station 116.

At block 212, the electronic device testing system 100 tests the devices. The electronic device testing system 100 may move the carrier and/or contactors of the testing station 116 such that the contactors make physical contact I/O points of the devices. The testing station 116 may lock the devices into a position in the coupons and/or lock the position of the coupons in the carrier. The testing station 116 may apply a test signal, e.g., a load, to the devices and measure one or more parameters on the devices in response to the test signal. The electronic device testing system 100 may record the results of the test for each device, such as the parameter values, and associate the results with the device.

At block 214, the electronic device testing system 100 transfers the tested devices out of the testing station 116. For example, the electronic device testing system 100 can move the carrier back onto a carrier retainer disk 109 and rotate the carrier retainer disk out of the testing station 116. At block 216, the electronic device testing system 100 transfers the tested devices from the carrier 108 to one or more trays. For example, the output station 118 may carry the tested devices from the coupons of the carrier 108 to the tray. At block 218, the electronic device testing system 100 transfers the tray of tested devices into the tray stacks 104. For example, the TPS 106 may carry a tray of tested devices from the thermal chamber 102 to the tray stacks 104. In various implementations, the electronic device testing system 100 may index and track the devices throughout process 200. For example, the electronic device testing system 100 may index the devices as they are transferred into the thermal chamber 102 and associate the results of the test with the indexed devices, such that as the devices are transferred into the trays and out of the thermal chamber 102, each individual device and test result are known for each position of the device in the tray.

According to various embodiments of the process 200, once the DUTs are individually transferred to a carrier using the PnP head, the DUTs are transferred within the system 100 (FIGS. 1A-1C) through usage of the carriers 108, without handling DUTs out of the carriers 108 as the DUTs are transferred though different stations. For example, blocks 206-214 above may be performed without removing the DUTs from the carriers 108. Unlike existing methods, once the DUTs are transferred 202 onto the carriers 108, the station-to-station transfers and testing of the DUTs are performed without removing them from the carriers 108, which greatly reduces device displacement events, as there may not be a need for handling the DUTs using, e.g., vacuum handlers. Until after the testing is completed. The reduced handling of the DUTs greatly reduces the probability of displacing the DUTs, which has traditionally been one of the biggest throughput limiters of IC testing.

### Carrier Assembly

As described above, usage of carriers allows for transfer and testing of DUTs without removing them from the coupons in the carrier, which greatly reduces device displacement events. Various examples of the carriers and coupons according to embodiments are disclosed herein.

FIGS. 3A-3E illustrate a carrier assembly 300 according to various embodiments. FIG. 3A illustrates a perspective view of the carrier assembly 300. FIG. 3B illustrates a bottom view of the carrier assembly 300. FIG. 3C illustrates a side view of the carrier assembly 300. FIG. 3D illustrates a partial side view of the carrier assembly 300 and a coupon retained therein. FIG. 3E illustrates a partial cross section of a carrier assembly 300 and coupons 304 retained therein. In some implementations, carrier assembly 300 can correspond to carrier 108 of FIGS. 1A-1C.

In the illustrated embodiment, carrier assembly 300 includes a carrier 302 (also referred to herein as a “body” of the carrier assembly) and one or more coupons 304. The carrier 302 has formed thereon a plurality of coupon receptacles 314 (also referred to as a “coupon pocket”) into which the coupons can be removably inserted. The coupon receptacles 314 can be arranged in an array, e.g., an array of rows and columns. The carrier 302 can include one or more alignment holes 306 and one or more alignment pins 310. It will be appreciated that for illustrative purposes only, the illustrated carrier assembly 300 includes eight total coupons 304, arranged in two rows of four coupons 304. However, other numbers of coupons 304 and other arrangements of coupons 304 may be used. For example, eight coupons 304 may be arranged in a single row of eight coupons 304. As another example, carrier assembly 300 may have a single coupon 304 or may have more than eight coupons 304 (e.g., 32 coupons 304). In some implementations, the coupons 304 are not arranged in rows.

As described in more detail in FIGS. 4A-4E below, each coupon 304 is configured to house a device, such as a DUT. As such, the carrier assembly 300 may be used to carry one or more DUTs throughout a device testing system, such as the electronic device testing system 100 of FIGS. 1A-1C.

Among other functions, the carrier 302 can provide structural support for the coupons 304. The carrier 302 can allow the coupons 304 to be securely transported without removing the coupons 304. The alignment holes 306 and alignment pins 310 can allow multiple carrier assemblies 300 to be stacked and/or otherwise facilitate the handling of the carrier assembly 300. For instance, the alignment pins 310 of a first carrier assembly 300 can be inserted into the alignment holes 306 of a second carrier assembly 300. The alignment pins 310 can include a spacer portion configured to provide a gap between a first carrier assembly 300 and a second carrier assembly 300 that are stacked. In some embodiments, the spacer portion is variable. For example, in some instances the spacer portion may be smaller, providing a smaller gap between the first carrier assembly 300 and the second carrier assembly 300. In some other instances, the spacer portion may be larger, providing a larger gap between the first carrier assembly 300 and the second carrier assembly 300. The size of the gap between the first carrier assembly 300 and the second carrier assembly 300 may influence one or more attributes of the carrier assemblies 300. For example, a larger gap may increase airflow and thereby increase the rate of temperature change of DUTs in the carrier assemblies 300 undergoing temperature adjustments (e.g., in thermal staging area 110 of FIGS. 1A-1C). While alignment holes 306 and alignment pins 310 are illustrated in FIGS. 3A-3C as having elongated cylindrical shapes, the carrier 302 may include other structures that facilitate the handling of the carrier assembly 300. For example, the carrier 302 may include machined corresponding features (e.g., machined polygonal structures such as rectangular or square features engaging with corresponding polygonal holes such as rectangular or square holes, machined oblong features engaging with corresponding oblong features, or other suitable machined features, or any combination thereof).

The inventors have discovered that under some circumstances, the contacting surfaces between the DUT and the plunger and/or the contacting surfaces between the DUT and the contactor may not be fully aligned with each other, e.g., not fully parallel to each other, such that when the plunger and/or the contactor engages with the DUT for testing, portions of corresponding surfaces of the DUT and the plunger and/or the corresponding surfaces of the DUT and the contactor intended to fully contact each other may form insufficient contact. For example, the corresponding surfaces may be tilted with respect to each other such that upon contact, one or more corners of the DUT may form no contact or insufficient contact with the plunger and/or the contactor. Such misalignment can cause insufficient thermal and/or electrical contact between the DUT and the plunger and/or the contactor.

To address these and other technical considerations, as discussed elsewhere in the application, the coupon 304 holding the DUT may, at times, have up to six degrees of freedom of movement within the coupon receptacle 314, including three independent linear degrees of freedom and three independent angular degrees of freedom, within predetermined tolerances. For example, linear degrees of freedom may allow for limited movements of the coupons in x, y and z perpendicular directions by more than 0.1 mm, 0.2 mm, 0.4 mm. 0.6 mm, 0.8 mm, 1.0 mm, 1.5 mm, 2 mm or a distance in a range defined by any of these values, and angular degrees of freedom may allow for limited tilting or rotations of the coupons about the x, y and z perpendicular axes crossing a central region of the coupon by more than 0.1°, 0.2°, 0.4°, 0.6°, 0.8°, 1.0°, 2°, 5°, or an angle in a range defined by any of these values. At other times, the coupon 304 may be secured within the coupon receptacle, restricting one or more degrees of freedom (e.g., a coupon 304 may be secured in the coupon receptacle 314 during testing of the DUT positioned therein and/or throughout the various transportation stages in an electronic device testing system 100).

The degrees of freedom may be provided by elastic members 312 (FIG. 3E) that elastically retain the coupons 304 within the coupon receptacles 314. The elastic members 312 can independently elastically elongate, thereby adjusting the coupon 304 in the coupon receptacle 314 into a testing position. In the testing position, the DUT retained in the coupon 304 can make electrical and physical contact with a contactor. As such, the degrees of freedom can help facilitate an alignment of a DUT with a contactor used in electrical testing of the DUT. In some embodiments, the degrees of freedom may allow the coupons to move within the carrier assembly 300 without damaging the DUT and/or dislodging the coupon from the carrier 302. As the elastic members 312 are elongated, the coupon receptacles 314 can be configured to accommodate movements of the coupons 304 within the coupon receptacles 314 in lateral and vertical directions within less than about 20%, 10%, 5%, 2%, or a value in a range defined by any of these values, of corresponding lateral dimensions of the DUT and/or coupons 304.

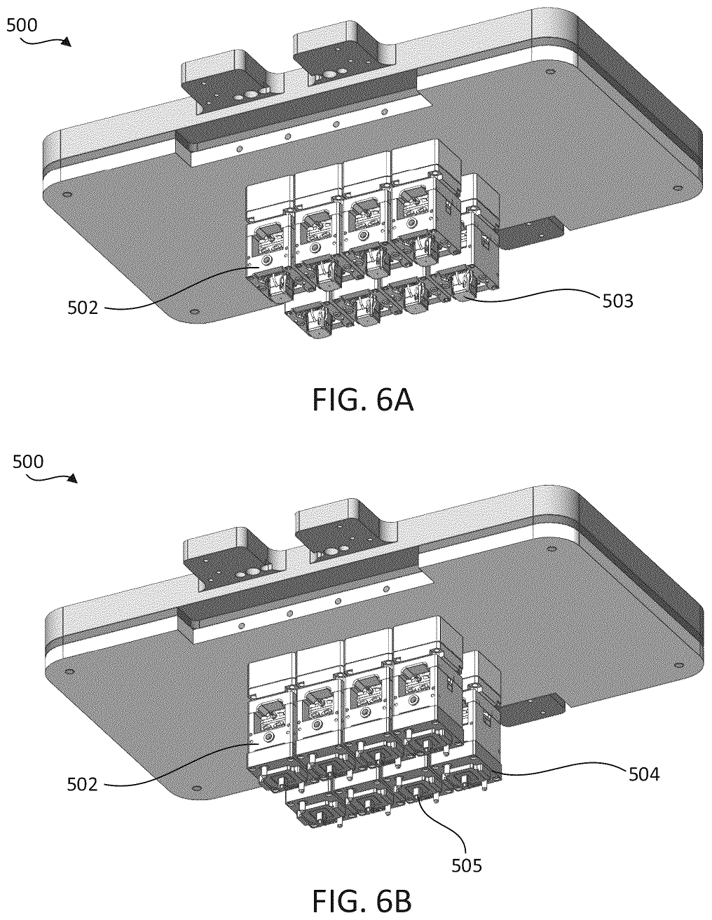

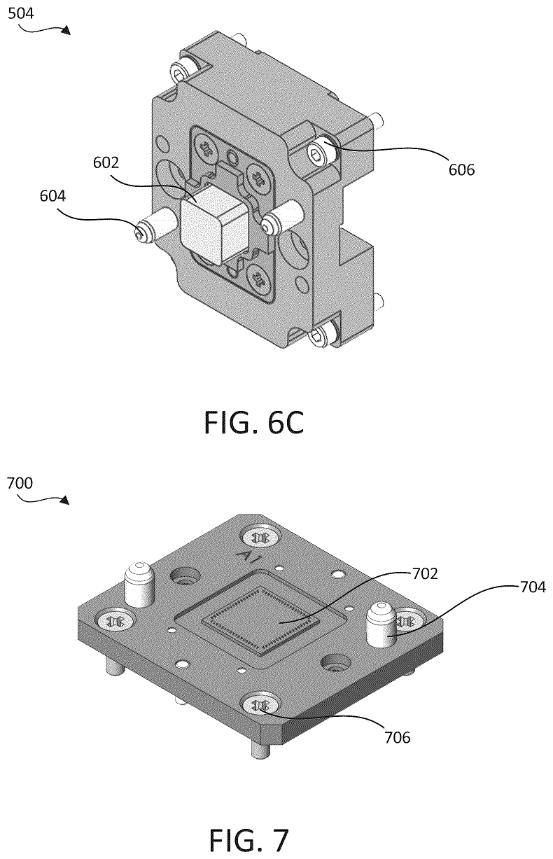

FIGS. 3D and 3E illustrate a displacement of a coupon 304 relative to a carrier 302 that may be implemented in a carrier assembly 300 according to various embodiments. As illustrated in FIG. 3D, in some implementations, a coupon 304 may be displaced by distance D₁ from the bottom of the carrier 302 in response to a force F₁. The D₁ may correspond to distance the DUT travels before contacting the contactor. When the coupon 304 is not displaced, the coupon 304 can be referred to as in a “default position.” When the coupon 304 is displaced (e.g., by distance D₁), the coupon 304 can be referred to as in a “testing position.” The distance D₁ may be physically limited by a stopping mechanism (not shown). In some implementations, the magnitude of the force and displacement of a coupon 304 may be tailored for providing physical contact between DUTs and a test socket or contactor for providing electrical access to the DUTs while remaining in the coupon 304. For example, in some instances, when the coupon 304 is displaced by distance D₁, the coupon 304 may be in a testing position in which the DUT makes electrical and physical contact with a test probe, such as a test socket or a contactor. In some implementations, force F₁, may be applied by a nest plunger (FIGS. 6A-6C) connected to a testing station, such as testing station 116 of FIGS. 1A-1C.

In some implementations, once the force F₁ is removed, the coupon 304 retracts along distance D₁ such that the coupon 304 is restored to the default position relative to the carrier 302 by an elastic retraction of the elastic members 312. For example, elastic members 312 may include one or more spring assemblies configured to return the coupon 304 to the default position once the force F₁ is removed. As illustrated in FIG. 3E, the elastic members 312 (e.g., a spring assembly) may be anchored in the carrier 302 and configured interact with the coupon 304 to apply a force that, at least in part, opposes the force F₁. In the illustrated example, the elastic members 312 are spring assemblies including a center anchor elastically attached by the spring assembly to the carrier 302, a ledge portion on an opposing end of the spring assembly, and a spring positioned between the carrier 302 and the ledge portion. The opposing ends of the spring may be attached to the ledge portion and the carrier 302. The center anchors can be inserted into holes in the coupon 304 (e.g., the holes 408 illustrated in FIGS. 4A-4C). In the default position of the coupon, the illustrated spring may be in an initial stretched state and elastically pulling the ledge portion, by an elastic force (e.g., force from the spring), towards a lower portion of the coupon 304 (e.g., opposite in direction to force F₁), thereby causing the coupon 304 to remain in the default position, absent other forces. Upon application of a force, the spring may further stretch at least by D₁, e.g., to a testing position. While FIG. 3E illustrates the elastic members 312 as spring assemblies, other embodiments may utilize other elastic members configured to cause the coupon 304 to remain in the default position, absent other forces. Examples of elastic members 312 can include, but are not limited to, compression springs, torsion springs, shear springs, elastic material, any other suitable device or material, or any combination thereof.

In some embodiments, the coupon receptacles 314 may include various configurations that fix (or partially fix) the coupon 304 from lateral movement while in the default position. In the illustrated example, the coupon receptacles 314 include beveled portions 315 that engage sloped portions 305 of the coupon 304. The beveled portions 315 and the sloped portions 305 can have approximate complementary cutout angles such that the coupon 304 fits within the beveled portions 315 in the keystone manner illustrated in FIG. 3E. As the coupon 304 is displaced along distance D₁, the sloped portions 305 separate from the beveled portions 315, allowing the movement of the coupons 304 within the coupon receptacles 314 described above.

Also illustrated in FIG. 3E, is a cross section of a coupon 304 with a DUT 406 retained therein. The coupon 304 can include one or more holders 404 and/or one or more holders 405 (also referred to as “device retaining latches”). The holders 404 and 405 may be configured to retain the DUT 406 within the coupon 304 during testing of the DUT 406 and as the carrier assembly 300 transfers through the various stations of an electronic device testing system. The holders 405 may include a lever position proximate to the DUT 406 but not applying any perpetual force on the DUT 406. The holders 404, may be used to ensure the DUT 406 remains in the carrier. The holders 404 may include a lever that applies a lateral force on the DUT 406, securing (or partially securing) the DUT 406 in a position in the coupon 304. In some embodiments, the position in the coupon may be an alignment position for testing the DUT 406. For example, one or more holders 404 may secure the DUT 406 in a corner of a device pocket 308 (also referred to as a “DUT” pocket) of the coupon 304 aligning the DUT 406 to a position within the coupon 304 that is aligned for testing. The holders 404 and holders 405 may include a mechanism for coupling, e.g., elastically coupling, the DUT using an elastic member such as a one or more springs. In the illustrated embodiment, without limitation the holders 404 and holders 405 comprise one more levers that are pivoted to provide the elastic force from the springs to the DUT. While both the holders 405 and holders 404 are illustrated in FIG. 3C, one or both the holders 405 and holders 404 may, in some embodiments, be omitted, or other components for securing the DUT 406 within the coupon may be used.

The holders 405 and holders 404 may include a disengagement mechanism (e.g., at the bottom of the holders 405 and holders 404) which may temporarily disengage the holders 405 and holders 404. For example, the disengagement mechanism may retract and compress one or more springs or other mechanisms and/or otherwise cause the holders 405 and holders 404 to disengage. When the DUTs 406 are loaded or unloaded from the coupons 304 (e.g., at the input station 107 or the output station 118), the disengagement mechanism can be used to disengage the holders 405 and holders 404 such that the DUTs 406 can freely be placed within or removed from the coupons 304.

FIGS. 4A-4E illustrate a coupon 304 according to various embodiments. FIG. 4A illustrates a perspective view of the coupon 304. FIG. 4B illustrates a top view of the coupon 304. FIG. 4C illustrates a bottom view of the coupon 304. FIG. 4D illustrates a cross section of the coupon 304. FIG. 4E illustrates a cross section of the coupon 304 with a DUT 406.

In the illustrated embodiment, the coupon 304 includes a device pocket or DUT pocket 308, a plurality of holes 408, and a plurality of holes 409. The DUT pocket 308 may be configured to receive and hold a DUT. The DUT pocket 308 can include an aligner 402, holders 404, and/or holders 405 (not illustrated in FIGS. 4A-4E). The aligner 402 may help align a DUT with testing contactors of a testing station. For example, the aligner 402 may include a central hole and a plurality of smaller holes, vias, or other throughways surrounding the central hole. The holes provide unhindered access to the DUT. For example, the smaller holes provide access to one or more I/O ports or pads of a DUT. For illustrative purposes only, the illustrated coupon 304 is configured to hold a 10×10 quad flat no-lead (“QFN”) package with 72 I/O ports. Some QFN packages include a thermally conductive pad, e.g., at a central region, and the central hole of the aligner 402 may provide thermal access thereto. As such, the aligner 402 includes 72 holes surrounding a central hole in a rectangular formation, where 16 holes are disposed along each side of the rectangle to correspond to the I/O ports of the QFN package. In some embodiments, the central hole may be configured to expose a substantial area of the DUT (e.g., an IC device). For example, in the illustrated embodiment, the central hole may be configured to expose more than half the length and width of the 10×10 DUT. In some other embodiments, the coupon 304 may be configured to hold quad flat package (“QFP”) packages, which includes leads extending from the sides of the package. In these embodiments, the holes provide access to one or more I/O leads. In some other embodiments, the coupon 304 may be configured to hold other DUTs with different packages. In these embodiments, the aligner 402 may be configured differently (e.g., with a different number and placement of holes) to accommodate the different packages.

The holders 404 (or holders 405) may hold a DUT, such as DUT 406, in the DUT pocket 308. The holders 404 may include a mechanism for coupling, e.g., elastically coupling, the DUT using an elastic member such as a one or more springs. In some embodiments, the elastic member may allow the DUT 406 some freedom of movement in the vertical direction without allowing the DUT 406 to dislodge from the DUT pocket 308. In the illustrated embodiment, without limitation the holders 404 comprise one more levers that are pivoted to provide the elastic force from the springs to the DUT.

To accommodate the changes in temperature the DUT may be subjected to during testing, the coupon 304 is formed of a suitable material. For example, the bottom surface of the coupon is formed of a material having a lower service temperature of −150° C., −100° C., −50° C., 0° C., or a temperature in a range defined by any of these values. The coupon may have an upper service temperature of 300° C., 250° C., 200° C., 150° C., 100° C., 50° C., or a temperature in a range defined by any of these values. For example, the coupon may be formed of a polymeric material such as polyimide.

The plurality of holes 409 may facilitate the alignment of the coupon 304 with one or more components of a testing station, such as testing station 116 of FIGS. 1A-1C. For example, some, or all, of the plurality of holes 409 may be configured to align the coupon 304 with contactors, sockets, plungers, and/or the like. The holes 408 may facilitate the coupling of the coupon 304 to a carrier, such as carrier assembly 300 of FIGS. 3A-3C. For example, some, or all, of the plurality of holes 408 may be configured to couple the coupon 304 to a carrier (e.g., using elastic members). The holes 309 may facilitate laterally securing a socket and/or a nest plunger, described in further detail elsewhere. In some embodiments, some, or all, of the holes 408 may include an elastic member (e.g., a spring assembly) therein. In these embodiments, the elastic members may be configured to allow the displacement discussed with respect to FIG. 4D.

Without limitation, the illustrated coupon 304 is adapted for logic ICs. Relative to memory chips, logic chips have a more complex, irregular layout to accommodate the various logic gates, control signals, and interconnections needed for processing and control. As a result, logic chips include a wide range of pins to handle input signals, output signals, control signals (e.g., clock, signal, power, etc.), and address/data signals. In contrast to logic chips, memory chips have fewer pins, as they function primarily to store and retrieve data, and can include pins for data input/output, address signals, and read/write signals. Thus, the device pocket of the illustrated coupon adapted for logic chips has a bottom surface adapted to accommodate a relatively a large number of pins, e.g., greater than 50, 100, 200, 500, 1000, 2000 or a number in a range defined by any of these values.

### Example Device Testing Components

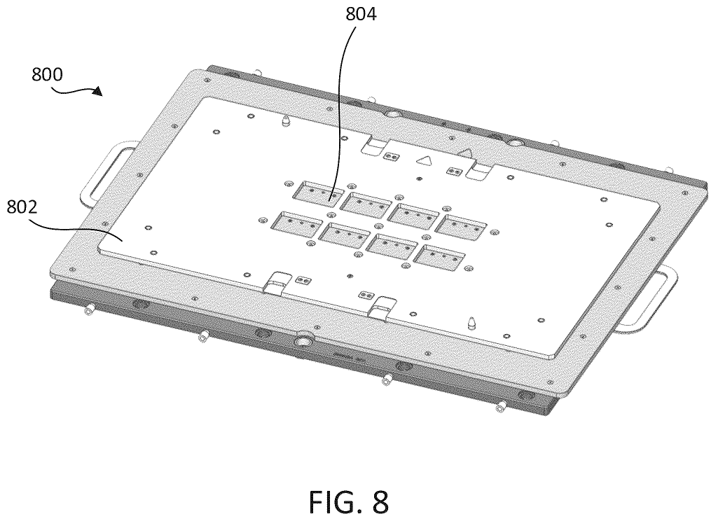

FIGS. 5A and 5B illustrated example aspects of testing DUTs using carriers and coupons. FIG. 5A illustrates portions of a testing station (e.g., testing station 116) according to various embodiments. The testing station 116 can include a socket layout kit (SLK) 500 with one or more plunger assemblies 502 positioned vertically above (or below) a carrier 108 with one or more DUTs positioned therein. The testing station 116 can include a contactor assembly 600 with a loadboard (e.g., loadboard 800 illustrated in FIG. 8; not shown in FIG. 5A) positioned vertically below (or above) the carrier 108.

According to various embodiments, prior to testing, the carrier 108 with DUTs previously loaded is positioned within the testing station 116 (e.g., by a carrier retainer disks 109). Once the carrier 108 is positioned within the testing station 116, the SLK 500 is lowered such that the one or more plunger assemblies 502 apply a force on the coupons positioned on the carrier 108, disposing the carriers into a testing position in which the DUTs make electrical and physical contact with contactors of the contactor assembly 600. As the plunger assemblies 502 apply the force to the coupons (e.g., as elastic members of the coupons elongate), but before the coupons are in the testing position, each coupon can have up to three independent angular degrees of freedom of movement within the coupon receptacle and up to three independent angular degrees of freedom of movement within the coupon receptacle. These degrees of freedom can allow the coupons and DUTs positioned therein to align with the contactors with an increased margin of error in the positioning of the plunger assemblies 502, the carrier 108, the coupons, the DUTs, and/or the contactors. In particular, higher error tolerance can allow for the DUTs to align into the testing position with improved contact between the DUTs and the plunger and/or the contactor. This increased margin of error can increase the success rate of test performance, decrease the need to retest DUTs, decrease the potential of damage to the DUTs or contactors, improve thermal control and/or provide other benefits described herein or apparent from this disclosure.

FIG. 5B illustrates a cross section of a testing site according to various embodiments. In the illustrate embodiment, the coupon is in a testing position with the DUT 406 in physical and electrical contact with the contactors 702. A plunger assembly 502 with a thermal head 503 and a pedestal 505 is illustrated as engaging the coupon 304 and/or the DUT 406. The thermal head 503, the pedestal 505, alignment features 604 (described below with respect to FIG. 6C), and supporting structures can collectively be referred to as a “nest plunger” (e.g., the nest plunger 504 illustrated in FIGS. 6B and 6C). Aspects of the one or more plunger assemblies 502 will be described in more detail below with respect to FIGS. 6A-6C.

During testing, the plunger assembly 502 can physically secure the coupon 304 in the testing position and/or the DUT 406 against the contactors 702. The thermal head 503 can provide thermal control (e.g., ATC or passive thermal control). For example, the thermal head 503 implements an ATC system that can raise and/or lower the temperature of the DUT 406 during testing. As another example the thermal head 503 may be a heat sink without active heat dissipation. In these embodiments, the 503 may have a thermal mass sufficient to conduct and dissipate the thermal energy from the DUT 406 during testing to maintain a testing temperature. The pedestal 505 may facilitate thermal conductions between the thermal head 503 and the DUT 406. For example, the pedestal 505 may comprise suitable thermally conductive materials to efficiently transfer thermal energy to and from the DUT 406 and the thermal head 503. The pedestal 505 may additionally provide a physical interface and provide a securing force on the DUT, such that the DUT 406 remails in a fixed position during electrical testing. In some embodiments, the pedestal 505 is omitted and the thermal head 503 contacts the DUT 406 directly.

The contactors 702 can be implemented on or integrated with a socket 700 (both described in more detail with respect to FIG. 7) and positioned on a loadboard 800 (described in more detail with respect to FIG. 8). The loadboard may be part of or attached to the contactor assembly 600 and raised up to coupons and DUTs (or remain stationary and have the coupons and DUTs lowered to) when the coupons are in the testing position.

FIGS. 6A and 6B illustrate an example SLK 500 according to various embodiments. FIG. 6A illustrates the SLK 500 with the thermal heads 503 of the plunger assemblies 502 exposed. FIG. 6B illustrates the SLK 500 with the nest plunger 504 applied.

FIG. 6C illustrates the nest plunger 504 (also referred to as a “nest”) according to various embodiments. The nest plunger 504 may be used to apply a force (e.g., force F₁ described above with respect to FIG. 3D) on a coupon 304 and/or a DUT. The nest plunger 504 may displace a coupon 304 relative to a carrier 302 of a carrier assembly 300 during testing of one or more DUTs. In the illustrated embodiment, the nest plunger 504 includes a plunger 602, alignment features 604, and fasteners 606.

The plunger 602 may be configured to be inserted into a DUT pocket 308 of a coupon 304 (FIG. 4A). The plunger 602 may include the thermal head 503 and/or the pedestal 505. The plunger 602 may contact the DUT and apply a force on the DUT and coupon, such that the DUT or coupon has restricted movement in at least a vertical axis, e.g., a z direction. As such, in some embodiments, a combination of the nest plunger 504 and the socket 700 of FIG. 7 may be used to restrict the movement (e.g., remove the six degrees of freedom of movement) of a DUT and/or coupon 304.

The alignment features 604 may be configured to be inserted into some, or all, of the plurality of holes 409 of a coupon 304. The alignment features 604 may help ensure alignment between the DUT pocket 308 and the plunger 602. In the illustrated embodiment, the alignment features 604 are configured to be inserted into the holes 409 at diagonal positions. The alignment features 604 may prevent the coupon 304 from moving laterally, e.g., in x and y directions, with respect to the nest plunger 504 (while allowing the lateral movement with respect to the contactor). The fasteners 606 may couple the nest plunger 504 the one or more plunger assemblies 502. The fasteners 606 can include screws, rivets, pins, and/or other fasteners.

FIG. 7 illustrates a socket 700 according to various embodiments. The socket 700 may be used in testing a DUT held in a coupon, such as coupon 304. In the illustrated embodiment, the socket 700 includes contactors 702, alignment features 704, and fasteners 706. The contactors 702 can be configured to contact the I/O ports of a DUT held in a coupon. For example, the contactors 702 can include one or more electrical contacts, probes, and/or the like configured to establish an electrical connection with the I/P ports of a DUT. The contactors 702 may be configured to deliver a test signal, e.g., a load, to the DUT.

The alignment features 704 may be configured to be inserted into some, or all, of the plurality of holes 409 of a coupon 304. In the illustrated embodiment, the alignment features 704 are configured to be inserted into holes 409 at diagonal positions. The alignment features 704 may help ensure alignment between the DUT and the contactors 702.

In some embodiments the contactors 702 and/or the alignment features 704 may lock a coupon in place during testing (e.g., the testing position and in alignment with the contactors 702). For instance, the contactors 702 and/or the alignment features 704 may remove one or more of the six degrees of movement of the DUT within the DUT pocket 308 such that the DUT remains fixed in place during testing. The coupons may be allowed limited movement until the alignment features 704 lock them in position for testing. The alignment features 704 can provide a simple securing mechanism for precise positioning the DUTs without using complex mechanisms such as vacuum chucks. While alignment features 604, alignment features 704, holes 408, and holes 409 are illustrated in various figures as having elongated cylindrical shapes, other features and shapes may be used to facilitate alignment and/or prevent lateral movement between the coupon 304 and the nest plunger 504 and/or between the coupon 304 and the socket 700. For example, the coupon 304, the nest plunger 504, and/or the socket 700 may include machined corresponding features (e.g., machined polygonal features such as rectangular or square features engaging with corresponding polygonal holes such as rectangular or square holes, machined oblong features engaging with corresponding oblong holes, or other suitable machined features, or any combination thereof).

The fasteners 706 may couple the socket 700 to a component of a testing station, such as the testing station 116. For example, in some implementations, the fasteners 706 couple the socket 700 to the loadboard 800 illustrated in FIG. 8. The fasteners 706 can include screws, rivets, pins, and/or other fasteners.

In some embodiments, the nest plunger 504 (e.g., the thermal head 503) and/or the socket 700 may be a component of an active thermal control (ATC) system configured for thermal management of the DUT during electrical testing. For example, the ATC system may raise and/or lower the temperature of the DUTs during testing. The ATC system may provide or carry away heat using one or more heat exchangers coupled to heat and/or cold sources. For example, the nest plunger 504 may include one or more heat sinks in thermal connection with a cooling source (e.g., a refrigerant, cold gases, liquid nitrogen, compressed clean dry air (CDA), and/or other cooling sources). The DUT may undergo thermal change during testing. For example, the test signal, or other electrical signal provided to the DUT by the socket 700, may cause a temperature of the DUT to rise. As another example, the temperature of the DUT may fall naturally and/or fall due to exposure to the one or more heat sinks. In these embodiments, the ATC system can utilize the nest plunger 504 and/or the socket 700 to alter and/or maintain the temperature of the DUT at a desired level (e.g., a testing temperature). In some implementations, the amount of heat provided to the DUT may be actively adjusted, e.g., offset, based on the amount of power delivered to the DUT as part of the testing signal. As configured, the coupon 304 (FIGS. 4A-4E) having a top opening configured to receive a plunger for ATC during testing, and having the access openings at the bottom configured for electrical contacts with a contactor for sending and receiving electrical test signals can be particularly suitable for testing logic devices such as microprocessors that may dissipate a large amount power, some of which dissipates as heat, which can exceed over 100 W, 200 W, 500 W, 1000 W, 2000 W, or a value in a range defined by any of these values.

FIG. 8 illustrates a loadboard 800 (also referred to as a “socket support frame”) according to various embodiments. The loadboard 800 may be part of a testing station, such as testing station 116. The loadboard 800 may be configured to raise one or more sockets, such as the socket 700, such that the sockets temporarily couple to a coupon 304 in a carrier assembly 300 in a manner described with respect to FIG. 7. In the illustrated embodiment, the loadboard 800 includes a plate 802 with a plurality of socket ports 804.

Each socket port 804 may be configured to couple to a socket, such as socket 700. For example, a socket 700 may be coupled to the socket port 804 using the fasteners 706. The number and arrangement of socket ports 804 may depend on the number and arrangements of coupons 304 in a carrier assembly 300. For example, FIG. 8 illustrates eight total socket ports 804, arranged in two rows of four socket ports 804, matching the arrangement of coupons 304 in the carrier assembly 300, illustrated in FIG. 3A-3C. However, other numbers and arrangements of socket ports 804 may be used to match other numbers and arrangements of coupons 304. In some embodiments, the 802 may be replaced on the loadboard 800 to accommodate a different number and arrangement of coupons 304 in a carrier assembly 300.

### Example Tray Precising System

Some existing IC testing systems use standard trays for transporting DUTs. Some trays are according to industry standards, set by organizations such as Joint Electronic Device Engineering Council (JEDEC). Trays according to standards set by JEDEC are sometimes referred to as JEDEC trays. However, some trays of DUTs, such as the trays of the tray stacks 104 illustrated in FIGS. 1A and 1B, which may be JEDEC trays, may cause problems associated with transferring DUTs when used in conjunction with a PnP system, including the PnP head 128 and the TPS 106 as described above with respect to FIGS. 1A-1C. In some instances, a position of each DUT in a tray may not have sufficient precision to reliably be indexed, lifted, carried, and/or placed in carriers in a testing system. For example, some trays may lack sufficient precision as manufactured, while some other trays may lose precision due to warping or other defects that can occur during manufacture of the trays and/or over time as the trays are used. In some other instances, the trays may become warped, such that when the input station 107 pushes down on a DUT to pick it up, another DUT at another location on the tray may move or displaced from its original location due to the elastic deformation of the tray. To address these and other problems with existing trays, disclosed herein is a tray precising system, which can include the PnP head 128 and the TPS 106, that can transport trays of DUTs and ensure precise placement of DUTs in the trays when unloading DUTs from and/or loading DUTs into the trays using a PnP or other system.

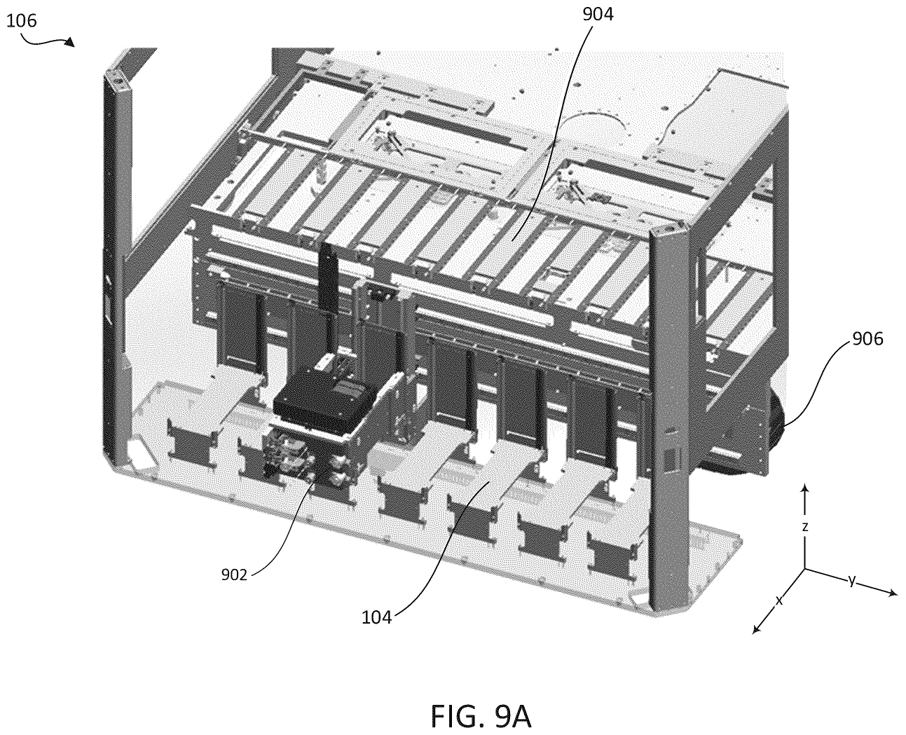

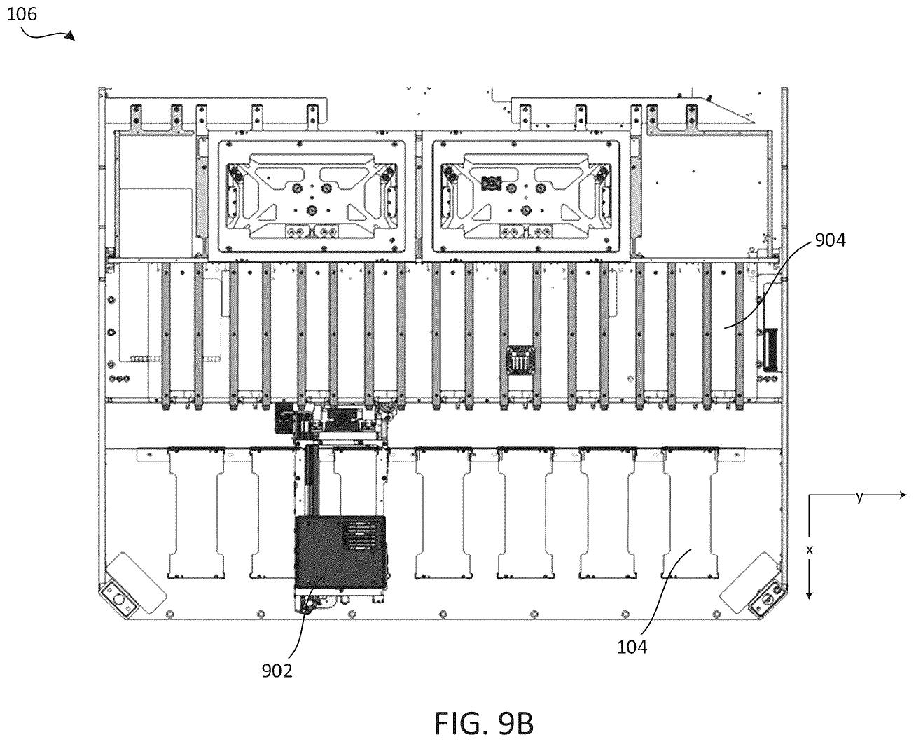

FIGS. 9A and 9B illustrate perspective and top-down views of a TPS 106 according to various embodiments. As described above, the TPS 106 can transfer trays (not shown) of DUTs from the tray stacks 104 into the electronic device testing system 100 (e.g., into the dry chamber 122 described above with respect to FIGS. 1A-1C). FIG. 9A illustrates the TPS 106 from a perspective view and FIG. 9B illustrates the TPS 106 from a top view. In the illustrated embodiment, the TPS 106 includes an automatic tray transfer (ATT) assembly 902, a lateral movement belt 906, and a TPS 106. The TPS 106 is physically disposed inside the dry chamber 122.

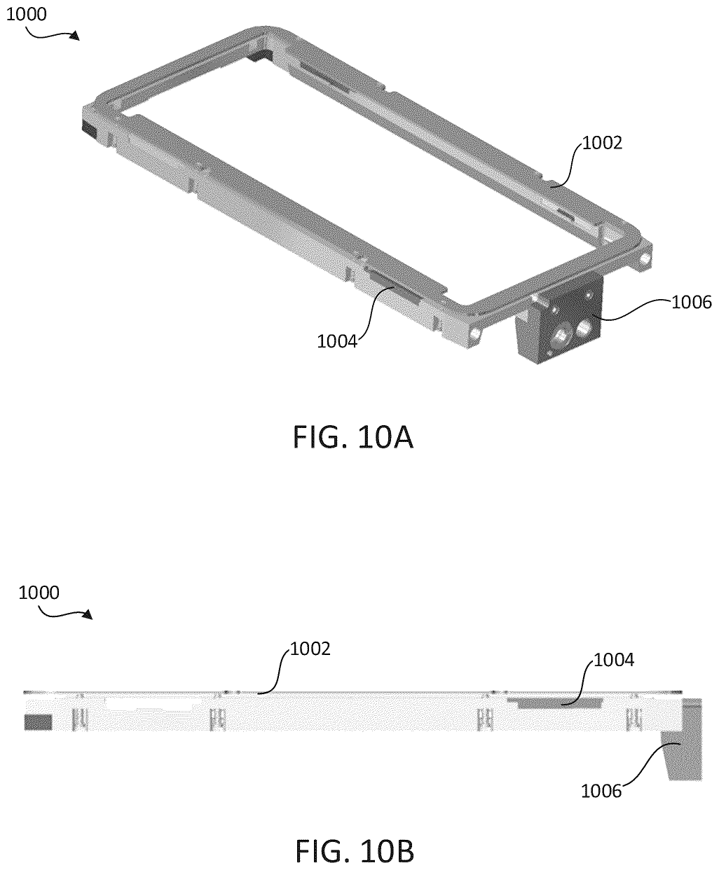

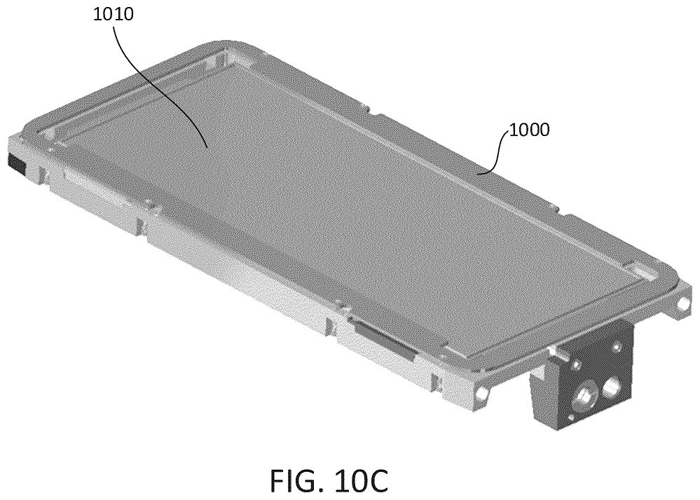

The ATT assembly 902 can lower (e.g., move downward in the z axis) one or more tray frames (e.g., tray frame 1000 described with respect to FIGS. 10A-4C) onto one or more trays of DUTs in the tray stack 104. As will be described in more detail below with respect to FIGS. 10A-4C, the tray frames can temporarily physically couple to the trays of the tray stacks 104. The tray frames can provide structural support such that, when the tray is coupled to the tray frame, the stability and precision of the positions of the DUTs within the tray can be enhanced. For example, the structural support of the tray frame can correct and/or compensate for lost precision due to warping or other defects.

The ATT assembly 902 can include as few as three motor drives. The ATT assembly 902 includes a first motor drive configured to transfer the tray frames along the z axis. The first motor drive is configured to move a tray frame down (e.g., move downward in the z-axis) to an uppermost tray of the track stack, latch on the uppermost tray, and raise (e.g., move upward in the z axis) one or more trays that are physically coupled to the tray frames off the tray stacks 104. The ATT assembly 902 additionally includes a second motor drive configured to drive the lateral movement belt 906, to move the one or more tray frames (which may have latched thereon a tray) laterally along the y axis to span across the tray stacks 104. ATT assembly 902 additionally includes a third motor drive configured to move the one or more trays laterally along the x axis into the TPS 106 in the dry chamber 122. As will be described in more detail with respect to FIGS. 5A-5C, once the ATT assembly 902 has raised the tray frame, the ATT assembly 902 may move the trays and the tray frames laterally (e.g., backwards on the x axis) into the TPS 106. The trays can remain in the tray frames while in the TPS 106 while a PnP system, including the PnP head 128 and the TPS 106, described above with respect to FIGS. 1A-1C, loads and/or unloads the DUTs from the tray. As such, the trays maintain the benefit of increased precision during loading and/or unloading in a PnP process, thereby increasing the effectiveness of the PnP system by reducing the probability of displacing the DUTs due to imprecise alignment. For illustrative purposes only, seven stacks of trays are shown in the tray stacks 104 and a different number of stacks of trays may be used. Further for illustrative purposes only, nine positions of trays and tray frames are shown in the TPS 106, and a different number of positions of trays and tray frames may be used.

In some embodiments, the tray stacks 104 may be positioned on the outside of a testing system (e.g., outside of the dry chamber 122 described above with respect to FIGS. 1A-1C) and TPS 106 may be positioned on the inside of the testing system (e.g., inside the dry chamber 122). As noted above, there can be a pressure difference between the one or both of the dry chamber 122 and the thermal chamber 102 (FIGS. 1A and 1B), and the area in which the tray stacks 104 are positioned. For example, the dry and thermal chambers 122, 102 may have a positive pressure, e.g., a positive pressure of dry gas such as air or nitrogen. The positive pressure may be maintained by a continuous purge of the dry and thermal chambers 122, 102 with the dry gas. Such configuration can keep moisture from condensing on the DUTs or other parts of the system, which can interfere with the testing. For example, without such purge, DUTs that are cooled may collect excessive moisture condensation. In these embodiments, the ATT assembly 902 may transport a tray from one pressure environment to another. For example, the ATT assembly 902 may transport the trays and tray frames through a door, and or another throughway, as the ATT assembly 902 moves the trays and the tray frames laterally (e.g., into the dry chamber 122 along the x axis) into the TPS 106.

As illustrated in FIGS. 9A and 9B, in some embodiments, one ATT assembly 902 may be used to load and/or unload trays from multiple stacks of trays in the tray stacks 104. Further, in these embodiments, the one ATT assembly 902 may be used to load and unload trays and tray frames from multiple positions in the TPS 106. The lateral movement belt 906 may be configured to move the ATT assembly 902 laterally (e.g., along the y axis), such that the ATT assembly 902 can be positioned to load and/or unload trays from any tray stack of the tray stacks 104 and the ATT assembly 902 can be positioned to load and/or unload trays and tray frames from any position in the TPS 106. The lateral movement belt 906 can be configured to move the ATT assembly 902 laterally (e.g., along the y axis).

FIGS. 10A-10C illustrate a tray frame 1000 according to various embodiments. FIG. 10A illustrates a perspective view of the tray frame 1000 and FIG. 10B illustrates a cross-sectional view of the tray frame 1000. FIG. 10C illustrates a perspective view of a tray frame 1000 having physically coupled thereon a tray 1100. In the illustrated embodiment, the tray frame 1000 includes a frame ring, a cover plate 1002, a plurality of tray grippers 1004, and an interface 1006. The tray frame has a frame ring configured to surround the tray received thereinto.

A tray, such as tray 1100, may be inserted into the bottom of the tray frame 1000. For example, the tray frame 1000 may be lowered onto a tray using an ATT assembly. When the tray is fully inserted into the tray frame 1000 the top of the tray physically contacts the cover plate 1002 and the plurality of tray grippers or latching mechanisms 1004 temporarily physically couple to or latches thereon the tray. The frame ring and/or the cover plate 1002 may be made of any rigid or partially rigid material. The rigid material is stiffer, e.g., has a higher Young's modulus, relative to the tray. For example, the rigid material may be a metal, e.g., aluminum or steel. The tray grippers 1004 may include springs, locking mechanisms, releasing mechanisms, and/or other components for temporarily physically coupling the trays.

Multiple tray grippers 1004 are used in the tray frame 1000. As such, the tray is held against the cover plate 1002 at multiple points allowing the tray frame 1000 to offset for warping, distortions, and/or other defects of the tray that may affect the precise location of DUTs on the tray without the tray frame 1000. Further, the tray frame 1000 may provide increased support to the tray, thereby securing the DUTs to decrease the likelihood of DUT displacement while the tray and the tray frame 1000 are transported (e.g., by an ATT assembly 902 illustrated in FIGS. 9A and 9B). For illustrative purposes only, FIGS. 10A-4C illustrate four tray grippers 1004. However, a different number of tray grippers 1004 may be used.

The interface 1006 may be configured to couple the tray frame 1000 to an ATT assembly (e.g., ATT assembly 902 illustrated in FIGS. 9A and 9B) and/or a tray input/output holder (e.g., TPS 106). In some implementations, interface 1006 includes a pneumatic ball lock for coupling the tray frame to an ATT assembly and/or or a tray input/output holder. In other implementations, the interface 1006 may be configured to couple to the tray frame to an ATT assembly and/or or a tray input/output holder in other ways, such as springs, latches, pins, screws, and/or temporary physically coupling components.

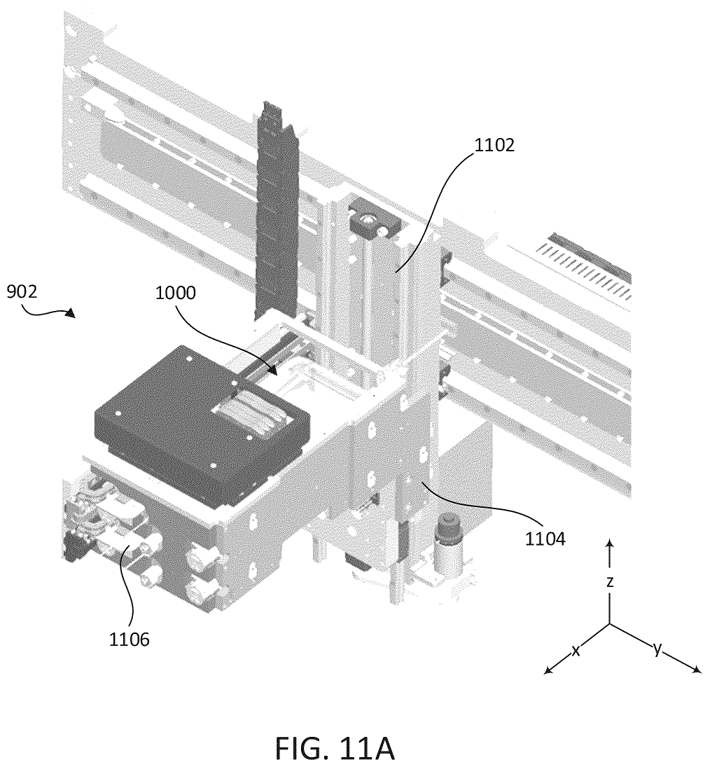

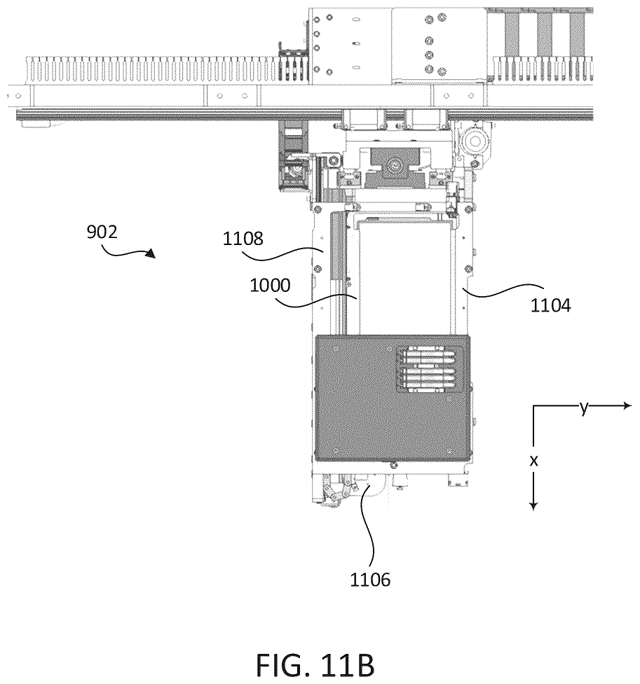

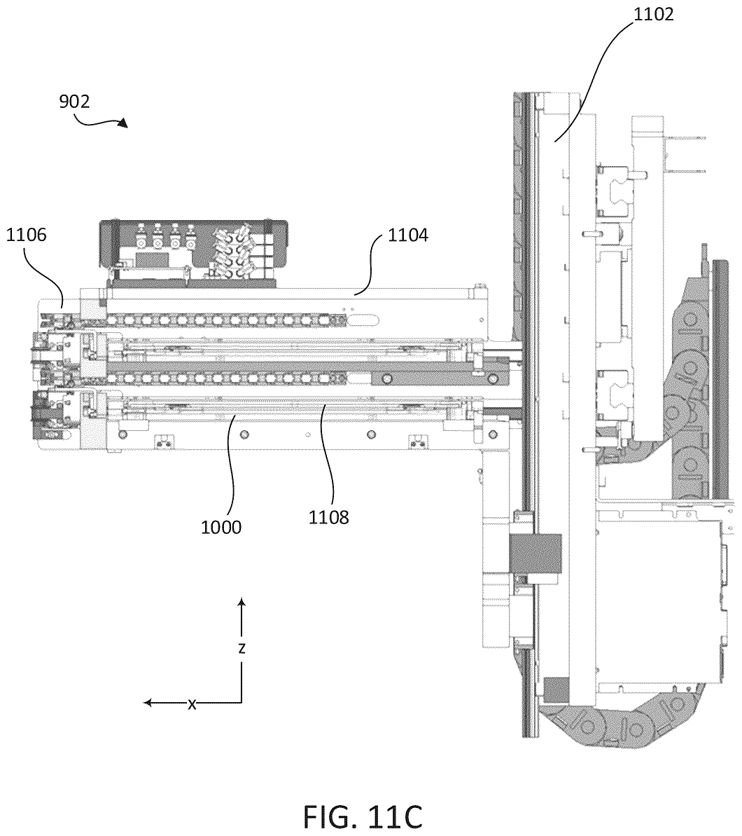

FIGS. 11A-11C illustrate a portion of an ATT assembly 902 according to various embodiments. In particular, the illustrated portion of the ATT assembly 902 shows components that may be involved in vertical (z) and horizontal (x) movement of the tray frames. FIG. 11A illustrates a perspective view of the portion of the ATT assembly 902, FIG. 11B illustrates a top view of the portion of the ATT assembly 902, and FIG. 11C illustrates a side view of the portion of ATT assembly 902. In the illustrated embodiment, the ATT assembly 902 includes a vertical mover 1102, a frame support structure 1104, frame connection arms 1106, and a lateral mover 1108.

In some embodiments, the ATT assembly 902 is configured to move one or more tray frames 1000 in the frame support structure 1104. In the illustrated embodiment, the ATT assembly 902 is configured to move the upper tray frame (not shown) and lower tray frame 1000 simultaneously along the z axis in the frame support structure 1104. In an input operation to load a loaded tray into the TPS 106, the upper tray frame may be used or configured, e.g., to receive and transfer an empty tray from the TPS 106. The lower tray frame 1000 may be designated or configured, e.g., to receive and transfer a loaded tray loaded with untested DUTs from a stack of trays holding untested DUTs.

In the input operation, as described above, the ATT assembly 902 can move (e.g., move downward in the z axis) the tray frames 1000 along the z axis and stop based on a signal from a look-across sensor detecting a top level of the stack of trays. The lower tray frame 1000 receives a tray from the bottom side and latches the tray thereto. The ATT assembly 902 can raise (e.g., move upward in the z axis) the two tray frames in conjunction. Once the ATT assembly 902 has raised the tray frames the ATT assembly 902 may move the upper tray frame, which may not have a tray latched thereon, vertically in position for inserting the upper tray frame into the TPS 106, move the upper tray frame 1000 laterally in the x direction into the TPS 106 to latch thereto an empty tray from the TPS 106, and move out the upper tray frame 1000 out in the x direction. Next, the ATT assembly 902 may move the lower tray frame 1000, which may have a loaded tray latched thereon, vertically in position for inserting the lower tray frame 1000 into the TPS 106, move the lower tray frame 1000 laterally in the x direction into the TPS 106, release the loaded tray onto TPS 106, and move out the lower tray frame 1000 out in the x direction.

In an output operation, to unload a loaded tray of tested DUTs from the TPS 106, the upper tray frame may be used or configured, e.g., to transfer an empty tray to the TPS 106. The lower tray frame 1000 may be designated or configured, e.g., to receive and transfer a loaded tray loaded with tested DUTs from the TPS 106 to a stack of trays holding tested DUTs.

In the output operation, as described above, the ATT assembly 902 can have an upper tray frame (not shown), which may have a tray latched thereon and a lower tray frame 1000, which may not have a tray latched thereon. The ATT assembly may move the lower tray frame 1000 laterally in the x direction into the TPS 106 to latch thereto a tray of tested DUTs from the TPS 106 and move out the lower tray frame 1000 out in the x direction. Next, the ATT assembly 902 may move the upper tray frame, which may have a tray latched thereon, vertically in position for inserting the upper tray frame into the TPS 106, move the upper tray frame laterally in the x direction into the TPS 106, release the tray onto TPS 106, and move out the upper tray frame, which now may not have tray latched thereon out in the x direction. The ATT assembly 902 can lower (e.g., move downward in the z axis) the two tray frames in conjunction. The ATT assembly can stop based on a signal from a look-across sensor detecting a top level of a stack of trays of tested DUTs. The lower tray frame 1000 can release the tray of tested DUTs from the bottom side of the lower tray frame 1000 onto the stack of trays of tested DUTs.

While the illustrated embodiment shows a frame support structure 1104 carrying two tray holders, embodiments are not so limited. It will be appreciated that the tray frames 1000 that move in conjunction can include one tray or three trays or more.

The frame support structures 1104 can temporality house one or more tray frames 1000. The tray frames 1000 can be coupled to the frame connection arms 1106. The frame connection arms 1106 can include one or more connectors configured to couple with the interface 1006 of the tray frame. For example, in one implementation, the frame connection arms 1106 include pneumatic ball connectors, springs, latches, pins, screws, and/or the like that can temporality couple the frame connection arms 1106 to the tray frame 1000.

The vertical mover 1102 can be configured to raise and lower (e.g., move along the z axis) the frame support structures 1104 and the frame connection arms 1106 (referred to collectively herein as the “tray frame holder”), thereby raising and lowering the tray frames 1000. The 1102 may lower the tray frames 1000 onto trays, such that the trays temporarily physically couple to the tray frames 1000. The vertical mover 1102 can include motors, hydraulic systems, and/or any other components for lowering and raising the tray frame holder.

The lateral mover 1108 can be configured to extend and retract (e.g., move along the x axis) the tray frames 1000 out and in of the tray frame holder. For example, the lateral mover 1108 may be used to extend the tray frames 1000 out of the tray frame holder and into a tray input/output holder and to retract the tray frames 1000 from the tray input/output holder into the tray frame holder. The lateral mover 1108 can include motors, hydraulic systems, and/or any other components for extending and retracting the tray frames 1000. The frame support structures 1104 can include one or more slots configured to allow the frame connection arms 1106 to travel as the tray frames 1000 are extended and retracted.

As described above, the PnP head 128 can carry DUTs from trays in TPS 106 and load them into carriers within a testing system (e.g., into input station 107 in the dry chamber 122 as described above with respect to FIGS. 1A-1C) to undergo testing. Once tested, the PnP head 128 can carry DUTs from the carriers within the testing system, to the trays in the TPS 106. As such, the TPS 106 and the PnP system can facilitate the loading of untested DUTs into a testing system, such as the electronic device testing system 100 illustrated in FIGS. 1A and 1B, and the unloading of tested DUTs from the testing system.

In some embodiments, the TPS 106 can include a device indexing system. The device indexing system can include, for example, an optical sensor configured identify indicators on trays, individual DUTs, carriers, coupons, and/or other components. The indicators can include, but are not limited to, bar codes (e.g., two dimensional bar codes), serial numbers, or other unique identifiers. The device indexing system can track the trays, individual DUTs, carriers, coupons, and/or other components throughout the testing process. For example, the device indexing system can read the indicators of devices as they are loaded into the electronic device testing system 100 by the TPS 106 and/or the input station 107, track the devices as they are transported to various stations within the electronic device testing system 100, and read the indicators of the devices as they are unloaded from the electronic device testing system 100 by the output station 118 and/or the TPS 106. The device indexing system can aid tracking of testing results, determining information associated with device displacement, and/or provide other information regarding the trays, individual DUTs, carriers, coupons, and/or other components.

### Additional Examples I

1. A coupon comprising a device pocket configured to retain an IC device therein during electrical testing of the IC device, the device pocket having a top opening for receiving the IC device and a bottom surface having formed therethrough a plurality of access openings configured to expose portions of the IC device.

2. The coupon of Embodiment 1, wherein the top opening is configured to receive a plunger for active temperature control during testing, and wherein the access openings are configured for electrical contacts with a contactor for sending and receiving electrical test signals.

3. The coupon of Embodiment 2, wherein the IC device is a logic processor.

4. The coupon of Embodiment 1, wherein the device pocket comprises one or more retaining holders configured to retain the IC device with a downward force.

5. The coupon of Embodiment 4, wherein the one or more holders comprise a pivoted lever.

6. The coupon of any one of the above Embodiments, wherein the one or more holders are configured to apply the downward force elastically using a spring.

7. The coupon of any one of the above Embodiments, wherein the access openings comprise electrical access openings configured to expose input and output (I/O) ports of the IC device for electrical access by a testing contactor to deliver testing signals.

8. The coupons of any one of the above Embodiments, wherein the access openings comprise a central access opening configured to expose a substantial area of the IC device.

9. The coupon of any one of the above Embodiments, wherein the bottom surface of the coupon is formed of a polymer material having a service temperature of −100° C. to 200° C.

10. The coupon of Embodiment 9, wherein the polymeric material comprises polyimide.

11. The coupon of any one of the above Embodiments, wherein the device pocket is arranged as a recess at a central location of a planar portion of the coupon extending laterally from edges of the device pocket.

12. The coupon of Embodiment 11, wherein the planar portion comprises a plurality of alignment holes configured to receive one or more alignment pins of a test socket to restrain a lateral movement of the coupon relative to the test socket, the test socket comprising a testing contactor for delivering testing signals to the IC device.

13. The coupon of Embodiment 11 or 12, wherein the planar portion comprises a plurality of alignment holes configured to receive one or more alignment pins of a plunger assembly to restrain a lateral movement of the coupon relative to the plunger assembly, the plunger assembly configured to apply a vertical force to the IC device for contacting the IC device to the testing contactor.

14. The coupon of Embodiment 13, wherein the coupon is configured to receive the alignment pins of the test socket at a back side thereof, and wherein the coupon is configured to receive the alignment pins of the plunger assembly from a front side thereof opposite to the back side.

15. The coupon of Embodiment 12-14, wherein the planar portion comprises a plurality of outer alignment holes configured to receive one or more alignment pins of a carrier configured to retain the coupon during testing of the IC device to restrain a lateral movement of the coupon relative to the carrier.

16. The coupon of any one of the above Embodiments, wherein the device pocket is dimensioned relative to the IC device such that the device pocket accommodates a movement or an expansion of the IC device within the device pocket in lateral directions within 1% of or less of corresponding lateral dimensions of the IC device.

17. The coupon of any one of the above Embodiments, wherein the coupon comprises a plurality of device pockets each configured to hold the IC device.

18. A carrier assembly for testing integrated circuit (IC) devices, the carrier assembly comprising a plurality of coupon pockets configured to hold a plurality of coupons therein, each coupon according to any one of Embodiments 1-17.

19. The carrier assembly of Embodiment 18, wherein each coupon pocket is configured to loosely retain one of the coupons by one or more springs such that the coupon has three independent linear degrees of freedom of movement and three independent angular degrees of freedom of movement.

20. The carrier assembly of Embodiment 18, wherein the carrier assembly is configured to be stacked with at least another one of carrier assemblies to form a stack of carrier assemblies.

21. The carrier assembly of Embodiment 20, wherein the carrier assembly comprises on a first side thereof a plurality of alignment holes configured to receive a plurality of alignment pins of another one of the carrier assemblies.

22. The carrier assembly of Embodiment 21, wherein the carrier assembly comprises on a second side thereof a plurality of alignment pins configured to be inserted into a plurality of alignment holes of another one of the carrier assemblies.

23. The carrier assembly of Embodiment 21, wherein the alignment pins comprise a wide base portion wider than corresponding alignment holes such that an air gap is formed between adjacent ones of the carrier assemblies of the stack of carrier assemblies.

24. The carrier assembly of any one of the above Embodiments, wherein the carrier assembly is further according to any one of the Embodiments in Additional Examples II.

25. A n apparatus for testing integrated circuit (IC) devices, the apparatus comprising a plurality of stations each comprising a carrier retainer disk configured to hold and transfer one or more carrier assemblies, wherein each carrier assembly is according to the carrier assembly of Embodiment 19.

26. The apparatus of Embodiment 25, wherein the plurality of stations comprises an input station, an output station and a testing station.

27. The apparatus of Embodiment 25 or 26, wherein the IC devices are individually transferred to and from an external tray to the carrier assembly by a pick-and-place handler.

28. The apparatus of any one of Embodiments 26-27, wherein the IC devices remain in the carrier assembly between the input station and the output station, including during testing in the testing station, without being removed from the carrier assembly.

29. The apparatus of any one of Embodiments 25-28, wherein the testing station is enclosed in a temperature controlled thermal chamber.

30. The apparatus of Embodiment 29, wherein the chamber is under a positive pressure greater than atmospheric pressure.

31. The apparatus of any one of Embodiments 25-30, wherein the plurality of stations circularly surrounds a central axis of the apparatus.

32. The apparatus of Embodiment 31, wherein the carrier retainer disk is configured to transfer the one or more carrier assemblies between adjacent ones of the stations by rotating around the central axis of the apparatus surrounded by the stations.

33. The apparatus of Embodiment 32, wherein each carrier retainer disk is configured to rotate about a vertical axis of the carrier retainer disk at a central location thereof.

34. The apparatus of Embodiment 33, wherein the carrier retainer disk is configured to rotate about the vertical axis by an angle substantially compensates for the rotation of the carrier retainer disk around the central axis of the apparatus, such that an angular orientation of the one or more carrier assemblies remain substantially constant as the one or more carrier assemblies are rotated about the central axis of the apparatus.

35. The apparatus of any one of the above Embodiments, wherein the apparatus is further according to any one of the Embodiments in Additional Examples II.

### Additional Examples II

1. A carrier assembly for testing an electronic device, the carrier assembly comprising:
a carrier comprising a coupon receptacle configured to engage therein a coupon, the coupon having a device pocket to retain therein a device under test (DUT) during electrical testing thereof and having one or more bottom openings for the DUT to contact a contactor during the electrical testing; and
a plurality of elastic members configured to be independently elastically elongated to adjust a position of the coupon in the coupon receptacle into a testing position in which the DUT makes electrical and physical contact with the contactor.

2. The carrier assembly of Embodiment 1, wherein the elastic members are configured to collectively fix the coupon in the coupon receptacle in a default position as engaged in the carrier prior to being tested in the testing position.

3. The carrier assembly of Embodiment 2, wherein the coupon in the testing position is disposed vertically farther away from the carrier relative to the default position.

4. The carrier assembly of Embodiment 1, wherein the elastic members are individually configured to provide limited three independent angular degrees of freedom of movement to the coupon within the coupon receptacle.

5. The carrier assembly of Embodiment 4, wherein the limited three independent angular degrees of freedom include a first angular degree of freedom about a first lateral axis within about 2 degrees, a second angular degree of freedom about a second lateral axis within about 2 degrees, and third angular degree of freedom about a vertical axis within about 5 degrees.

6. The carrier assembly of Embodiment 1, wherein elastic members are individually configured to provide limited three independent linear degrees of freedom of movement to the coupon within the coupon receptacle.

7. The carrier assembly of Embodiment 6, wherein the limited three independent linear degrees of freedom include a first linear degree of freedom in a first lateral direction within about 1 mm, a second linear degree of freedom in a second lateral direction within about 1 mm, and a third linear degree of freedom in a vertical direction within about 1.5 mm.

8. The carrier assembly of Embodiment 2, wherein after the electrical testing of the DUT in the testing position, the elastic members are configured to retract back to dispose the coupon into the default position.

9. The carrier assembly of Embodiment 1, wherein the elastic members comprise one or more spring assemblies.

10. The carrier assembly of Embodiment 1, wherein the elastic members comprise two elastic members adjacent opposing edges of the coupon.

11. The carrier assembly of Embodiment 1, wherein the device pocket of the coupon includes a top opening for receiving the DUT and a bottom surface having formed therethrough the one or more bottom openings configured to expose portions of the DUT for making the electrical and physical contact with the contactor.

12. The carrier assembly of Embodiment 11, wherein the top opening of the coupon is configured to receive a nest plunger to contact the DUT for thermal management of the DUT thereof during the electrical testing.

13. The carrier assembly of Embodiment 12, wherein the carrier assembly is configured such that, in the testing position, opposing surfaces of the DUT contact the contactor and the nest plunger.

14. The carrier assembly of Embodiment 12, wherein the nest plunger comprises an alignment feature configured to align the nest plunger with the coupon.

15. The carrier assembly of Embodiment 12, wherein the nest plunger comprises a thermal head configured to provide active thermal control to the DUT during the electrical testing.

16. The carrier assembly of Embodiment 1, wherein the coupon receptacle comprises a beveled portion configured to engage the coupon and restrict lateral movement of the coupon with respect to the carrier.

17. The carrier assembly of Embodiment 16, wherein during the electrical testing, the beveled portion is configured to separate from the coupon and allow the lateral movement of the coupon with respect to the carrier.

18. The carrier assembly of Embodiment 1, wherein the coupon is configured for testing the DUT comprising a logic integrated circuit device.

19. An apparatus for testing an electronic device, the apparatus comprising:
a testing station configured to receive a carrier assembly carrying a device under test (DUT) and perform electrical testing on the DUT in the carrier assembly; and
the carrier assembly comprising:
   a carrier comprising a coupon receptacle configured to engage therein a coupon, the coupon having a device pocket to retain therein the DUT during the electrical testing thereof and having one or more bottom openings for the DUT to contact a contactor during the electrical testing, and
   a plurality of elastic members configured to be independently elastically elongated to adjust a position of the coupon in the coupon receptacle into a testing position in which the DUT makes electrical and physical contact with the contactor.

20. The apparatus of Embodiment 19, wherein the testing station comprises:
a contactor assembly comprising the contactor configured to electrically and physically contact with the DUT at a first side of the coupon in the testing position; and
a nest plunger configured for thermal management of the DUT and to physically contact the DUT at a second side of the coupon in the testing position.

21. The apparatus of Embodiment 20, wherein the apparatus comprises a plurality of stations including the testing station, wherein the carrier assembly rotates through the plurality of stations on a carrier retainer disk without being removed from the carrier retainer disk.

22. The apparatus of Embodiment 21, wherein at least the testing station is enclosed in a temperature-controlled testing chamber.

23. The apparatus of Embodiment 22, wherein the apparatus is configured such that the DUT is configured to be placed in the device pocket outside of the temperature-controlled testing chamber and to remain in the device pocket while the DUT is in the temperature-controlled testing chamber.

24. The apparatus of Embodiment 22, wherein the apparatus is configured such that the coupon is configured to be engaged into the carrier outside of the temperature-controlled testing chamber and to remain in the carrier while the coupon is in the temperature-controlled testing chamber.

25. The apparatus of Embodiment 19, wherein the elastic members are configured to collectively fix the coupon in the coupon receptacle in a default position as engaged in the carrier prior to being tested in the testing position.

26. The apparatus of Embodiment 25, wherein the coupon in the testing position is disposed vertically farther away from the carrier relative to the default position.

27. The apparatus of Embodiment 19, wherein the elastic members are individually configured to provide limited three independent angular degrees of freedom of movement within the coupon receptacle.

28. The apparatus of Embodiment 27, wherein the limited three independent angular degrees of freedom include a first angular degree of freedom about a first lateral axis within about 2 degrees, a second angular degree of freedom about a second lateral axis within about 2 degrees, and third angular degree of freedom about a vertical axis within about 5 degrees.

29. The apparatus of Embodiment 19, wherein the elastic members are individually configured to provide limited three independent linear degrees of freedom of movement within the coupon receptacle.

30. The apparatus of Embodiment 29, wherein the limited three independent linear degrees of freedom include a first linear degree of freedom in a first lateral direction within about 1 mm, a second linear degree of freedom in a second lateral direction within about 1 mm, and a third linear degree of freedom in a vertical direction within about 1.5 mm.

31. The apparatus of Embodiment 25, wherein after the electrical testing of the DUT in the testing position, the elastic members are configured to retract back to dispose the coupon into the default position.

32. The apparatus of Embodiment 19, wherein the elastic members comprise one or more spring assemblies.

33. The apparatus of Embodiment 22, wherein the plurality of stations further comprises a soak station configured to bring a temperature of the DUT closer to a testing temperature while the DUT is retained in the coupon of the carrier assembly.

34. The apparatus of Embodiment 33, wherein the soak station is disposed in the temperature-controlled testing chamber.

35. The apparatus of Embodiment 33, further comprising a carrier retainer disk configured to move the carrier assembly from the soak station to the temperature-controlled testing chamber.

36. The apparatus of Embodiment 19, wherein the device pocket of the coupon includes a top opening for receiving the DUT and a bottom surface having formed therethrough the one or more bottom openings configured to expose portions of the DUT for making the electrical and physical contact with the contactor.

37. The apparatus of Embodiment 20, wherein the nest plunger comprises an alignment feature configured to align the nest plunger with the coupon.

38. The apparatus of Embodiment 20, wherein the nest plunger comprises a thermal head configured to provide active thermal control to the DUT during the electrical testing.

39. The apparatus of Embodiment 19, wherein the coupon receptacle comprises a beveled portion configured to engage the coupon and restrict lateral movement of the coupon with respect to the carrier.

40. The apparatus of Embodiment 39, wherein during the electrical testing, the beveled portion is configured to separate from the coupon and allow the lateral movement of the coupon with respect to the carrier.

41. The apparatus and/or device transportation assembly of any one of the above Embodiments, wherein the apparatus and/or carrier assembly is further according to any one of the Embodiments in Additional Examples I or III.

42. A method of testing an electronic device, the method comprising:
providing a carrier assembly carrying a device under test (DUT) in a testing station to perform electrical testing on the DUT, wherein the carrier assembly comprises:
   a carrier comprising a coupon receptacle configured to engage therein a coupon, the coupon having a device pocket to retain therein the DUT during the electrical testing thereof and having one or more bottom openings for the DUT to contact a contactor during the electrical testing, and
   a plurality of elastic members configured to be independently elastically elongated to adjust a position of the coupon in the coupon receptacle into a testing position in which the DUT makes electrical and physical contact with the contactor;
adjusting the coupon into the testing position; and
performing the electrical testing on the DUT in the carrier assembly.

43. The method of Embodiment 42, wherein the testing station comprises:
a contactor assembly comprising the contactor configured to electrically and physically contact with the DUT at a first side of the coupon in the testing position; and
a nest plunger configured for thermal management of the DUT and to physically contact the DUT at a second side of the coupon in the testing position.

44. The method of Embodiment 43, further comprising:
wherein adjusting the position of the coupon into the testing position includes contacting opposing surfaces of DUT with contactor and the nest plunger.

45. The method of Embodiment 42, further comprising:
prior to providing the carrier assembly in the testing station, placing the DUT in the device pocket, wherein the DUT remains in the device pocket while the DUT is in the testing station;
removing the carrier assembly from the testing station; and
removing the DUT from the device pocket.

46. The method of Embodiment 42, further comprises, prior to performing the electrical testing, using the elastic members to collectively fix the coupon in the coupon receptacle in a default position as engaged in the carrier.

47. The method of Embodiment 46, further comprising after the electrical testing, disposing, by the elastic members, the coupon to the default position.

48. The method of Embodiment 46, wherein the coupon in the testing position is disposed vertically farther away from the carrier relative to the default position.

49. The method of Embodiment 42, wherein the elastic members are individually configured to provide limited three independent angular degrees of freedom of movement within the coupon receptacle.

50. The method of Embodiment 49, wherein the limited three independent angular degrees of freedom include a first angular degree of freedom about a first lateral axis within 2 degrees, a second angular degree of freedom about a second lateral axis within about 2 degrees, and third angular degree of freedom about a vertical axis within about 5 degrees.

51. The method of Embodiment 42, wherein the elastic members are individually configured to provide limited three independent linear degrees of freedom of movement within the coupon receptacle.

52. The method of Embodiment 51, wherein the limited three independent linear degrees of freedom include a first linear degree of freedom in a first lateral direction within about 1 mm, a second linear degree of freedom in a second lateral direction within about 1 mm, and a third linear degree of freedom in a vertical direction within about 1.5 mm.

53. The method of Embodiment 46, wherein after the electrical testing of the DUT in the testing position, the elastic members are configured to retract back to dispose the coupon into the default position.

54. The method of Embodiment 42, wherein the elastic members comprise one or more spring assemblies.

55. The method of Embodiment 42, further comprising:
prior to providing the carrier assembly in the testing station, adjusting a temperature of the DUT closer to a testing temperature in the coupon of the carrier assembly in a soak station;
moving the carrier assembly from the soak station to the testing station.

56. The method of Embodiment 42, wherein the device pocket includes a top opening for receiving the DUT and a bottom surface having formed therethrough a plurality of access openings configured to expose portions of the DUT.

57. The method of Embodiment 43, wherein the nest plunger comprises a thermal head configured to provide active thermal control to the DUT during the electrical testing.

58. The method of Embodiment 42, wherein the coupon receptacle comprises a beveled portion configured to engage the coupon and restrict lateral movement of the coupon with respect to the carrier.

### Additional Examples III

1. A device transportation assembly for transporting integrated circuit (IC) devices into and out of an electronic device testing system, the device transportation assembly comprising:
a tray frame configured to couple a device tray thereon, the device tray configured to hold a plurality of IC devices;
a tray frame carrier configured to hold one or more tray frames; and
an automatic tray transfer (ATT) assembly configured to couple thereon the tray frame carrier and to move the tray frame carrier in lateral and vertical directions.

2. The device transportation assembly of Embodiment 1, wherein the tray frame has a frame ring configured to surround the device tray received thereinto.

3. The device transportation assembly of Embodiment 2, wherein the frame ring has a bottom opening configured for receiving therethrough the device tray.

4. The device transportation assembly of Embodiment 3, wherein the tray frame further comprises a plurality of latching mechanisms on inner sidewalls of the frame ring for latching the device tray received through the bottom opening.

5. The device transportation assembly of Embodiment 4, wherein the tray frame further comprises a cover frame ring over a top opening of the frame ring and having an opening smaller than that of the device tray.

6. The device transportation assembly of Embodiment 2, wherein the frame ring is formed of a material that has a higher stiffness relative to that of the device frame.

7. The device transportation assembly of Embodiment 6, wherein the frame ring is formed of a metal.

8. The device transportation assembly of any one of the above Embodiments, wherein the tray frame carrier is configured to carry two tray frames.

9. The device transportation assembly of any one of the above Embodiments, wherein the tray frame carrier is configured such that the tray frame is slidingly received into the frame carrier and slidingly removed from the frame carrier.

10. The device transportation assembly of any one of the above Embodiments, wherein the device transportation assembly is configured to be coupled to a dry chamber, the dry chamber having disposed therein a tray precising station (TPS) for holding the device tray.

11. The device transportation assembly of Embodiment 10, wherein the ATT assembly comprises a first mover assembly for slidingly moving the tray frame in the tray frame carrier in a first lateral (x) direction towards and away from the tray input/output holder to pick up the device tray therefrom or release the device tray thereto.

12. The device transportation assembly of Embodiment 10, wherein the ATT assembly comprises a second mover assembly for moving the tray frame carrier in a vertical (z) direction towards and away from a vertical position for picking up the device tray from and releasing the device tray onto the tray input/output holder.

13. The device transportation assembly of Embodiment 10, wherein the ATT assembly comprises a third mover assembly for moving the tray frame carrier in a second lateral (y) direction towards and away from a horizontal position for picking up the device tray from and releasing the device tray onto the tray input/output holder.

14. An apparatus for testing integrated circuit (IC) devices, comprising:
an input station for placing a device under test (DUT) into a carrier assembly from a device tray;
an output station for removing the DUT from the carrier assembly to an empty device tray;
a testing station is configured to receive the carrier assembly carrying the DUT and perform electrical testing on the DUT in the carrier assembly without removing the DUT therefrom;
a device transportation assembly for transporting the device tray and the empty device tray, the device transportation assembly comprising:
   one or more tray frames each configured to couple the device tray and the empty device tray,
   a tray frame carrier configured to hold one or more tray frames, and
   an automatic tray transfer (ATT) assembly configured to couple thereon the tray frame carrier and to move the tray frame carrier in lateral and vertical directions.

15. The apparatus of Embodiment 14, wherein the apparatus comprises a tray precising station (TPS) disposed in a dry chamber under a positive pressure greater than atmospheric pressure of clean dry air or inert gas, the tray input/output holder configured to hold a device tray.

16. The apparatus of Embodiment 15, wherein the apparatus further comprises a thermal chamber coupled to the dry chamber, the thermal chamber under a positive pressure greater than atmospheric pressure of temperature-controlled clean dry air or inert gas.

17. The apparatus of Embodiment 16, comprising a plurality of stations each comprising a carrier retainer disk configured to hold and transfer a carrier assembly.

18. The apparatus of Embodiment 15, wherein the dry chamber encloses the input station, wherein the TPS is configured to place the DUT into the carrier assembly disposed on the input station using a pick-and-place handler.

19. The apparatus of Embodiment 15, wherein the dry chamber encloses the output station, wherein the TPS is configured to receive the DUT from the carrier assembly disposed on the output station using the pick-and-place handler.

20. The apparatus of Embodiment 17, wherein the plurality of stations includes a testing station.

21. The apparatus of Embodiment 20, wherein the DUT remains in the carrier assembly between the input station and the output station, including during testing in the testing station, without being removed from the carrier assembly.

22. The apparatus of Embodiment 17, wherein the plurality of stations circularly surrounds a central axis of the apparatus.

23. The apparatus of Embodiment 22, wherein the carrier retainer disk is configured to transfer the carrier assembly between adjacent ones of the stations by rotating around the central axis of the apparatus.

24. The apparatus of Embodiment 23, wherein each carrier retainer disk is configured to rotate about a vertical axis of the carrier retainer disk at a central location thereof.

25. The apparatus of Embodiment 24, wherein the carrier retainer disk is configured to rotate about the vertical axis by an angle substantially compensates for the rotation of the carrier retainer disk around the central axis of the apparatus, such that an angular orientation of the one or more carrier assemblies remain substantially constant as the one or more carrier assemblies are rotated about the central axis of the apparatus.

26. The apparatus of any one of the above Embodiments, wherein the apparatus and/or the carrier assembly is further according to any one of the Embodiments in Additional Examples I or II.

27. A method of transporting integrated circuit (IC) devices into and out of an electronic device testing system, the method comprising:
providing a device transportation assembly comprising:
   a plurality of tray frames, each configured to couple a device tray thereon, the device tray configured to hold a plurality of IC devices;
   a tray frame carrier configured to hold one or more of the tray frames; and
   an automatic tray transfer (ATT) assembly configured to couple thereon the tray frame carrier and to move the tray frame carrier in lateral and vertical directions;
moving, using the ATT, the a first tray frame and a first device tray thereon from a tray stack into the electronic device testing system;
testing the IC devices from the first device tray; and
moving a second tray and a second device tray thereon from the electronic device testing system to the tray stack.

28. The method of Embodiment 27, wherein testing the IC devices comprises:
moving the IC devices from the first device tray to one carrier of a plurality of carriers;
transferring the one carrier into a testing chamber;
performing one or more electrical tests on the IC devices while the IC devices are on the carrier;
transferring the one carrier out of the testing chamber; and
moving the IC devices from the one carrier to the second device tray.

29. The method of Embodiment 28, further comprising:
providing a tray precising system (TPS) configured to pick and place the IC devices between decoupled device trays and carriers;
decoupling the first device tray from the first tray frame;
wherein moving the IC devices from the first device tray to the one carrier is performed using the TPS, and
wherein moving the IC devices from the one carrier to the second device tray is performed using the TPS; and
coupling the second device tray to the second device tray.

30. The method of any one of the above Embodiments, wherein the method is further according to any one of the Embodiments in Additional Example II.

Unless the context clearly requires otherwise, throughout the description and the embodiments, the words “comprise,” “comprising,” “include,” “including,” and the like are to be construed in an inclusive sense, as opposed to an exclusive or exhaustive sense; that is to say, in the sense of “including, but not limited to.” Additionally, the words “herein,” “above,” “below,” and words of similar import, when used in this application, shall refer to this application as a whole and not to any particular portions of this application. Where the context permits, words in the Detailed Description using the singular or plural number may also include the plural or singular number, respectively. The words “or” in reference to a list of two or more items, is intended to cover all of the following interpretations of the word: any of the items in the list, all of the items in the list, and any combination of the items in the list. All numerical values provided herein are intended to include similar values within a measurement error.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states.

The teachings provided herein can be applied to other systems, not necessarily the systems described above. The elements and acts of the various embodiments described above can be combined to provide further embodiments. The acts of the methods discussed herein can be performed in any order as appropriate. Moreover, the acts of the methods discussed herein can be performed serially or in parallel, as appropriate.

While certain embodiments have been described, these embodiments have been presented by way of example only, and are not intended to limit the scope of the disclosure. Indeed, the novel methods and systems described herein may be embodied in a variety of other forms. Furthermore, various omissions, substitutions and changes in the form of the methods and systems described herein may be made without departing from the spirit of the disclosure. For example, while the disclosed embodiments are presented in given arrangements, alternative embodiments may perform similar functionalities with different components and/or circuit topologies, and some elements may be deleted, moved, added, subdivided, combined, and/or modified. Each of these elements may be implemented in a variety of different ways as suitable. Any suitable combination of the elements and acts of the various embodiments described above can be combined to provide further embodiments. The accompanying claims and their equivalents are intended to cover such forms or modifications as would fall within the scope and spirit of the disclosure. Accordingly, the scope of the present inventions is defined by reference to the claims.

1-18. (canceled)

19. An apparatus for testing an electronic device, the apparatus comprising:
a testing station configured to receive a carrier assembly carrying a device under test (DUT) and perform electrical testing on the DUT in the carrier assembly; and
the carrier assembly comprising:
a carrier comprising a coupon receptacle configured to engage therein a coupon, the coupon having a device pocket to retain therein the DUT during the electrical testing thereof and having one or more bottom openings for the DUT to contact a contactor during the electrical testing, and
a plurality of elastic members configured to be independently elastically elongated to adjust a position of the coupon in the coupon receptacle into a testing position in which the DUT makes electrical and physical contact with the contactor.

20. The apparatus of claim 19, wherein the testing station comprises:
a contactor assembly comprising the contactor configured to electrically and physically contact with the DUT at a first side of the coupon in the testing position; and
a nest plunger configured for thermal management of the DUT and to physically contact the DUT at a second side of the coupon in the testing position.

21. The apparatus of claim 20, wherein the apparatus comprises a plurality of stations including the testing station, wherein the carrier assembly rotates through the plurality of stations on a carrier retainer disk without being removed from the carrier retainer disk.

22. The apparatus of claim 21, wherein at least the testing station is enclosed in a temperature-controlled testing chamber.

23. The apparatus of claim 22, wherein the apparatus is configured such that the DUT is configured to be placed in the device pocket outside of the temperature-controlled testing chamber and to remain in the device pocket while the DUT is in the temperature-controlled testing chamber.

24. The apparatus of claim 22, wherein the apparatus is configured such that the coupon is configured to be engaged into the carrier outside of the temperature-controlled testing chamber and to remain in the carrier while the coupon is in the temperature-controlled testing chamber.

25. The apparatus of claim 19, wherein the elastic members are configured to collectively fix the coupon in the coupon receptacle in a default position as engaged in the carrier prior to being tested in the testing position.

26. The apparatus of claim 25, wherein the coupon in the testing position is disposed vertically farther away from the carrier relative to the default position.

27. The apparatus of claim 19, wherein the elastic members are individually configured to provide limited three independent angular degrees of freedom of movement within the coupon receptacle.

28. The apparatus of claim 27, wherein the limited three independent angular degrees of freedom include a first angular degree of freedom about a first lateral axis within about 2 degrees, a second angular degree of freedom about a second lateral axis within about 2 degrees, and third angular degree of freedom about a vertical axis within about 5 degrees.

29. The apparatus of claim 19, wherein the elastic members are individually configured to provide limited three independent linear degrees of freedom of movement within the coupon receptacle.

30. The apparatus of claim 29, wherein the limited three independent linear degrees of freedom include a first linear degree of freedom in a first lateral direction within about 1 mm, a second linear degree of freedom in a second lateral direction within about 1 mm, and a third linear degree of freedom in a vertical direction within about 1.5 mm.

31. The apparatus of claim 25, wherein after the electrical testing of the DUT in the testing position, the elastic members are configured to retract back to dispose the coupon into the default position.

32. The apparatus of claim 19, wherein the elastic members comprise one or more spring assemblies.

33. The apparatus of claim 22, wherein the plurality of stations further comprises a soak station configured to bring a temperature of the DUT closer to a testing temperature while the DUT is retained in the coupon of the carrier assembly.

34. The apparatus of claim 33, wherein the soak station is disposed in the temperature-controlled testing chamber.

35. The apparatus of claim 33, further comprising a carrier retainer disk configured to move the carrier assembly from the soak station to the temperature-controlled testing chamber.

36. The apparatus of claim 19, wherein the device pocket of the coupon includes a top opening for receiving the DUT and a bottom surface having formed therethrough the one or more bottom openings configured to expose portions of the DUT for making the electrical and physical contact with the contactor.

37. The apparatus of claim 20, wherein the nest plunger comprises an alignment feature configured to align the nest plunger with the coupon.

38. The apparatus of claim 20, wherein the nest plunger comprises a thermal head configured to provide active thermal control to the DUT during the electrical testing.

39. The apparatus of claim 19, wherein the coupon receptacle comprises a beveled portion configured to engage the coupon and restrict lateral movement of the coupon with respect to the carrier.

40. The apparatus of claim 39, wherein during the electrical testing, the beveled portion is configured to separate from the coupon and allow the lateral movement of the coupon with respect to the carrier.

41-57. (canceled)
